(19) United States
(12) Patent Application Publication
(10) Pub. No.: US 2023/0205087 A1
(43) Pub. Date: Jun. 29, 2023

(54) PHOTORESIST UNDERLAYER COMPOSITION

(71) Applicant: ROHM AND HAAS ELECTRONIC MATERIALS KOREA LTD., Cheonan-si (KR)

(72) Inventors: Min Kyung Jang, Hwaseong (KR); HyeonWoo Shin, Hwaseong (KR); Kijung Jung, Hwaseong (KR)

(21) Appl. No.: 18/085,082

(22) Filed: Dec. 20, 2022

Related U.S. Application Data
(60) Provisional application No. 63/294,569, filed on Dec. 29, 2021.

(51) Int. Cl. G03F 7/11; G03F 7/039; G03F 7/028; G03F 7/34

(52) U.S. Cl. CPC G03F 7/11; G03F 7/028; G03F 7/039; G03F 7/343

(57) ABSTRACT

A photoresist underlayer composition comprising a first polymer comprising a first structural unit derived from an N-(alkoxymethyl) (meth)acrylic amide monomer; a second structural unit comprising an aromatic group, a heterocyclic group, an ester group, an amide group, or a combination thereof, wherein the second structural unit further comprises a crosslinkable group; wherein the first polymer comprises the second structural unit, the photoresist underlayer composition further comprises a second polymer comprising the second structural unit, or a combination thereof, a thermal acid generator; and a solvent.

### FIELD

The present invention relates generally to field of manufacturing electronic devices, and more specifically to the field of materials for use in semiconductor manufacture.

### BACKGROUND

Photoresist underlayer compositions are used in the semiconductor industry as etch masks for lithography in advanced technology nodes for integrated circuit manufacturing. These compositions are often used in tri-layer and quad-layer photoresist integration schemes, where an organic or silicon containing anti-reflective coating and a patternable photoresist film layers are disposed on the bottom layer.

An ideal photoresist underlayer material should possess certain specific characteristics: it should be capable of being cast onto a substrate by a spin-coating process, should be thermally set upon heating with low out-gassing and sublimation, should be soluble in common solvents for good spin bowl compatibility, should have appropriate n & k values to work in conjunction with the anti-reflective coating layer to impart low reflectivity necessary for photoresist imaging, and should have high thermal stability to avoid being damaged during later processing steps. In addition to these requirements, the ideal photoresist underlayer material has to provide a planar film upon spin-coating and thermal curing over a substrate with topography and sufficient dry etch selectivity to silicon-containing layers located above and below the photoresist underlayer films in order to transfer the photo-patterns into the final substrate in an accurate manner.

Accordingly, there remains a need for new lower-layer materials, such as photoresist underlayer materials, which have improved adhesion to underlying substrates, solvent resistance after cure, and high thermal stability (e.g., reduced sublimation during cure).

### SUMMARY

Provided is a photoresist underlayer composition comprising a first polymer comprising a first structural unit derived from an N-(alkoxymethyl) (meth)acrylic amide monomer; a second structural unit comprising an aromatic group, a heterocyclic group, an ester group, and amide group, or a combination thereof, wherein the second structural unit further comprises a crosslinkable group; wherein the first polymer comprises the second structural unit, the photoresist underlayer composition further comprises a second polymer comprising the second structural unit, or a combination thereof, a thermal acid generator; and a solvent.

Also provided is a coated substrate comprising a layer of the photoresist underlayer composition disposed on a substrate; and a second layer disposed on the layer of the photoresist underlayer composition.

Still another aspect provides a method of forming a pattern comprising applying a layer of the photoresist underlayer composition on a substrate; curing the applied photoresist underlayer composition to form a photoresist underlayer; and forming a photoresist layer over the photoresist underlayer.

### BRIEF DESCRIPTION OF THE DRAWINGS

FIGS. 1A to 1D show microscope images of patterns coated with the underlayer compositions of Example 1, Comparative Example 1, Example 6, and Comparative Example 3, respectively, as provided herein.

FIG. 2A shows scanning electron microscope (SEM) results for patterns obtained using the underlayer compositions of Example 1 and Comparative Example 1, as described herein.

FIG. 2B shows SEM results for patterns obtained using the underlayer compositions of Example 6 and Comparative Example 3, as described herein.

### DETAILED DESCRIPTION

Reference will now be made in detail to exemplary embodiments, examples of which are illustrated in the present description. In this regard, the present exemplary embodiments may have different forms and should not be construed as being limited to the descriptions set forth herein. Accordingly, the exemplary embodiments are merely described below, by referring to the figures, to explain aspects of the present description. As used herein, the term “and/or” includes all combinations of one or more of the associated listed items. Expressions such as “at least one of,” when preceding a list of elements, modify the entire list of elements and do not modify the individual elements of the list.

As used herein, the terms “a,” “an,” and “the” do not denote a limitation of quantity and are to be construed to cover both the singular and the plural, unless otherwise indicated herein or clearly contradicted by context. “Or” means “and/or” unless clearly indicated otherwise. All ranges disclosed herein are inclusive of the endpoints, and the endpoints are independently combinable with each other. The suffix “(s)” is intended to include both the singular and the plural of the term that it modifies, thereby including at least one of that term. “Optional” or “optionally” means that the subsequently described event or circumstance can or cannot occur, and that the description includes instances where the event occurs and instances where it does not. The terms “first,” “second,” and the like, herein do not denote an order, quantity, or importance, but rather are used to distinguish one element from another. When an element is referred to as being “on” another element, it may be directly in contact with the other element or intervening elements may be present therebetween. In contrast, when an element is referred to as being “directly on” another element, there are no intervening elements present. It is to be understood that the described components, elements, limitations, and/or features of aspects may be combined in any suitable manner in the various aspects.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

As used herein, “actinic rays” or “radiation” means, for example, a bright line spectrum of a mercury lamp, far ultraviolet rays represented by an excimer laser, extreme ultraviolet rays (EUV light), X-rays, particle rays such as electron beams and ion beams, or the like. In addition, in the present invention, “light” means actinic rays or radiation. The krypton fluoride laser (KrF laser) is a particular type of excimer laser, which is sometimes referred to as an exciplex laser. “Excimer” is short for “excited dimer,” while “exciplex” is short for “excited complex.” An excimer laser uses a mixture of a noble gas (argon, krypton, or xenon) and a halogen gas (fluorine or chlorine), which under suitable conditions of electrical stimulation and high pressure, emits coherent stimulated radiation (laser light) in the ultraviolet range. Furthermore, “exposure” in the present specification includes, unless otherwise specified, not only exposure by a mercury lamp, far ultraviolet rays represented by an excimer laser, X-rays, extreme ultraviolet rays (EUV light), or the like, but also writing by particle rays such as electron beams and ion beams.

As used herein, the term “hydrocarbon” refers to an organic compound or group having at least one carbon atom and at least one hydrogen atom; “alkyl” refers to a straight or branched chain saturated hydrocarbon group having the specified number of carbon atoms and having a valence of one; “alkylene” refers to an alkyl group having a valence of two; “hydroxyalkyl” refers to an alkyl group substituted with at least one hydroxyl group (—OH); “alkoxy” refers to “alkyl—O—”; “carboxyl” and “carboxylic acid group” refer to a group having the formula “—C(O)OH”; “cycloalkyl” refers to a monovalent group having one or more saturated rings in which all ring members are carbon; “cycloalkylene” refers to a cycloalkyl group having a valence of two; “alkenyl” refers to a straight or branched chain, monovalent hydrocarbon group having at least one carbon-carbon double bond; “alkenoxy” refers to “alkenyl—O—”; “alkenylene” refers to an alkenyl group having a valence of two; “cycloalkenyl” refers to a non-aromatic cyclic divalent hydrocarbon group having at least three carbon atoms, with at least one carbon-carbon double bond; “alkynyl” refers to a monovalent hydrocarbon group having at least one carbon-carbon triple bond; the term “aromatic group” refers to a monocyclic or polycyclic aromatic ring system that satisfies Huckel’s Rule (4n+2 π electrons) and includes carbon atoms in the ring; the term “heteroaromatic group” refers to an aromatic group that includes one or more heteroatoms (e.g., 1-4 heteroatoms) instead of a carbon atom(s) in the ring; “aryl” refers to a monovalent monocyclic or polycyclic aromatic ring system where every ring member is carbon, and may include a group with an aromatic ring fused to at least one cycloalkyl or heterocycloalkyl ring; “arylene” refers to an aryl group having a valence of two; “alkylaryl” refers to an aryl group that has been substituted with an alkyl group; “arylalkyl” refers to an alkyl group that has been substituted with an aryl group; “aryloxy” refers to “aryl—O—”; and “arylthio” refers to “arylS—”.

The prefix “hetero” means that the compound or group includes at least one member that is a heteroatom (e.g., 1, 2, 3, or 4 or more heteroatom(s)) instead of a carbon atom, wherein the heteroatom(s) is each independently N, O, S, Si, or P; “heteroatom-containing group” refers to a substituent group that includes at least one heteroatom; the term “heterocycloalkyl” refers to a cycloalkyl group having at least one heteroatom as a ring member instead of carbon; and the term “heterocycloalkylene” refers to a heterocycloalkyl group having a valence of two. The term “heteroaryl” means 4-8 membered monocyclic, 8-12 membered bicyclic, or 11-14 membered tricyclic aromatic ring systems having 1-4 heteroatoms (if monocyclic), 1-6 heteroatoms (ifbicyclic), or 1-9 heteroatoms (if tricyclic).

The prefix “halo” means a group including one or more of a fluoro, chloro, bromo, or iodo substituent instead of a hydrogen atom. The term “halogen” means a monovalent substituent that is fluorine (fluoro), chlorine (chloro), bromine (bromo), or iodine (iodo). A combination of halogen groups (e.g., bromo and fluoro), or only fluoro groups may be present. The term “substituted C₁₋₈ haloalkyl” refers to a C₁₋₈ alkyl group substituted with at least one halogen, and is further substituted with one or more other substituent groups that are not halogen.

Each of the foregoing substituent groups optionally may be substituted unless expressly provided otherwise. The term “optionally substituted” refers to being substituted or unsubstituted. “Substituted” means that at least one hydrogen atom of the chemical structure or group is replaced with another terminal substituent group that is typically monovalent, provided that the designated atom’s normal valence is not exceeded. When the substituent is oxo (i.e., O), then two geminal hydrogen atoms on the carbon atom are replaced with the terminal oxo group. It is further noted that the oxo group is bonded to carbon via a double bond to form a carbonyl (C═O), where the carbonyl group is represented herein as —C(O)—. Combinations of substituents or variables are permissible. Exemplary substituent groups that may be present on a “substituted” position include, but are not limited to, nitro (—NO₂), cyano (—CN), hydroxyl (—OH), oxo (O), amino (—NH₂), mono- or di-(C₁₋₆)alkylamino, alkanoyl (such as a C₂₋₆ alkanoyl group such as acyl), formyl (—C(O)H), carboxylic acid or an alkali metal or ammonium salt thereof; esters (including acrylates, methacrylates, and lactones) such as C₂₋₆ alkyl esters (—C(O)O—alkyl or —OC(O)—alkyl) and C₇₋₁₃ aryl esters (—C(O)O—aryl or —OC(O)—aryl); amido (—C(O)NR₂ wherein R is hydrogen or C₁-₆ alkyl), carboxamido (—CH₂C(O)NR₂ wherein R is hydrogen or C₁₋₆ alkyl), halogen, thiol (—SH), C₁₋₆ alkylthio (—S—alkyl), thiocyano (—SCN), C₁₋₆ alkyl, C₂₋₆ alkenyl, C₂₋₆ alkynyl, C₁₋₆ haloalkyl, C₁₋₉ alkoxy, C₁₋₆ haloalkoxy, C₃₋₁₂ cycloalkyl, C₅₋₁₈ cycloalkenyl, C₂₋₁₈ heterocycloalkenyl, C₆₋₁₂ aryl having at least one aromatic ring (e.g., phenyl, biphenyl, naphthyl, or the like, each ring either substituted or unsubstituted aromatic), C₇₋₁₉ arylalkyl having 1 to 3 separate or fused rings and from 6 to 18 ring carbon atoms, arylalkoxy having 1 to 3 separate or fused rings and from 6 to 18 ring carbon atoms, C₇₋₁₂ alkylaryl, C₃₋₁₂ heterocycloalkyl, C₃₋₁₂ heteroaryl, C₁₋₆ alkyl sulfonyl (—S(O)₂—alkyl), C₆₋₁₂ arylsulfonyl (—S(O)₂—aryl), or tosyl (CH₃C₆H₄SO₂—).

As used herein, when a definition is not otherwise provided, a “divalent linking group” refers to a divalent group including one or more of —O—, —S—, —Te—, —Se—, —C(O)—, —C(O)O—, —N(R)—, —C(O)N(R)—, —S(O)—, —S(O)₂—, —C(S)—, —C(Te)—, —C(Se)—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein each R′ is independently hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl. Typically, the divalent linking group includes one or more of —O—, —S—, —C(O)—, —C(O)O—, —N(R′)—, —C(O)N(R)—, —S(O)—, —S(O)₂—, substituted or unsubstituted C₁₋₃₀ alkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, or a combination thereof, wherein R′ is hydrogen, substituted or unsubstituted C₁₋₂₀ alkyl, substituted or unsubstituted C₁₋₂₀ heteroalkyl, substituted or unsubstituted C₆₋₃₀ aryl, or substituted or unsubstituted C₃₋₃₀ heteroaryl.

As used herein, the term “(meth)acrylic” includes both acrylic and methacrylic species (i.e., acrylic and methacrylic monomers), and the term “(meth)acrylate” includes both acrylate and methacrylate species (i.e., acrylate and methacrylate monomers).

Organic underlayer films may be used to protect underlying substrates during various pattern transfer and etch processes. Often these films are cast and cured directly upon an inorganic substrate (i.e., TiN). In these cases, it is desirable that the underlayer film has sufficient adhesion to the substrate during all subsequent processing steps to protect the substrate from otherwise damaging conditions. Common wet etch processes involve submerging the substrate into a caustic solvent bath. An underlayer film that is not sufficiently adhered to the substrate may delaminate while it is submerged, resulting in exposure of and damage to the underlying inorganic substrate.

The incorporation of a structural unit derived from an N-(alkoxymethyl) (meth)acrylic amide in a polymer unit of a photoresist underlayer material can substantially improve solvent resistance after cure and thermal stability, without significantly compromising etch resistance and reflectivity parameters, and in some instances improving the collapse margin. When used in a photoresist underlayer composition, the structural unit derived from the N-(alkoxymethyl) (meth)acrylic amide may form crosslinks and/or may be crosslinkable, preferably wherein the polymer is crosslinkable without irradiation. The photoresist underlayer composition of the present invention further includes a thermal acid generator (TAG) and preferably does not include a photoacid generator (PAG). The crosslinking may be via a crosslinking agent or by self-crosslinking.

According to an aspect of the invention, a photoresist underlayer composition includes a first polymer comprising a first structural unit derived from an N-(alkoxymethyl) (meth)acrylic amide monomer; a second structural unit comprising an aromatic group, a heterocyclic group, an ester group, an amide group, or a combination thereof, wherein the second structural unit further comprises a crosslinkable group; a thermal acid generator; and a solvent. In the photoresist underlayer composition, the first polymer may include the second structural unit, or the photoresist underlayer composition may further include a second polymer comprising the second structural unit, or both the first polymer and the second polymer may each include the second structural unit.

In some embodiments, the first polymer may include a first structural unit derived from an N-(alkoxymethyl) (meth)acrylic amide monomer and a second structural unit comprising an aromatic group, a heterocyclic group, an ester group, an amide group, or a combination thereof, wherein the second structural unit further includes a crosslinkable group.

As used herein, “a crosslinkable group” refers to a nucleophilic group that includes oxygen, nitrogen, or sulfur such as hydroxyl (—OH), carboxyl (—C(O)OH), amine (—NH₂), thiol (—SH), vinyl (e.g., C₂₋₃₀ alkenyl), or amido (—C(O)NH₂). Other examples of crosslinkable groups may include those such as epoxies and lactones, for example epoxy, β-propiolactone, γ-butyrolactone, or δ-valerolactone. The crosslinkable group may be bonded to the aromatic group and/or the heterocyclic group either directly (via a single bond) or through a divalent linking group.

In some embodiments, the photoresist underlayer composition may include a first polymer comprising a first structural unit derived from an N-(alkoxymethyl) (meth)acrylic amide monomer and a second polymer, wherein the second polymer includes a second structural unit comprising an aromatic group, a heterocyclic group, or a combination thereof, wherein the second structural unit further comprises a crosslinkable group.

In still other embodiments, the first polymer may include a first structural unit derived from an N-(alkoxymethyl) (meth)acrylic amide monomer and a second structural unit comprising a first aromatic group, a first heterocyclic group, a first ester group, a first amide group, or a combination thereof, and wherein the second structural unit further includes a first crosslinkable group, and the photoresist underlayer composition may further include a second polymer that comprises a third structural unit, wherein the third structural unit comprises a second aromatic group, a second heterocyclic group, a second ester group, a second amide group, or a combination thereof, and wherein the third structural unit further comprises a second crosslinkable group. It is to be understood that the first aromatic group and the second aromatic group may be the same or different, the first heterocyclic group and the second heterocyclic group may be the same or different, the first ester group and the second ester group may be the same or different, the first amide group and the second amide group may be the same or different, and the first crosslinkable group and the second crosslinkable group may be the same or different.

The second structural unit includes an aromatic group, a heterocyclic group, an ester group, an amide group, or a combination thereof. As used herein, “an ester group” indicates a group of the formula —C(O)O— or —O(CO)—. As used herein, “an amide group” indicates a group of the formula —C(O)NR— or —RNC(O)—, wherein R is hydrogen, a substituted or unsubstituted C₁₋₂₀ alkyl group, or a substituted of unsubstituted C₆₋₆₀ aryl group. As used herein, “an aromatic group” refers to a monocyclic or polycyclic C₆₋₆₀ aromatic group. When the C₆₋₆₀ aromatic group is polycyclic, the ring or ring groups can be fused (such as naphthyl or the like), or directly linked (such as biaryls, biphenyl, or the like). In an embodiment, the polycyclic aromatic group may include a combination of fused and directly linked ring or ring groups (such as binaphthyl or the like). As used herein, “a heterocyclic group” refers to a monocyclic or polycyclic C₃₋₆₀ heteroaromatic group or a monocyclic or polycyclic C₃₋₆₀ heterocycloalkyl group. When the C₃₋₆₀ heteroaromatic group and/or the C₃₋₆₀ heterocycloalkyl is polycyclic, the ring or ring groups can be fused, directly linked, or a combination of fused and directly linked ring or ring groups.

In some embodiments, the first polymer may comprise the first structural unit derived from an N-(alkoxymethyl) (meth)acrylic amide monomer and a second structural unit comprising a C₆₋₆₀ aryl group and the crosslinkable group. The C₆₋₆₀ aryl group can be further substituted with other substituents besides the crosslinkable group, or may be unsubstituted except for the crosslinkable group. Exemplary substituents may include one or more of substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄-₃₀ alkylheteroaryl, or substituted or unsubstituted C₄₋₃₀ heteroarylalkyl. The crosslinkable group may be connected directly to a carbon atom of the C₆₋₆₀ aryl group, or the crosslinkable group may be linked via a divalent linking group of the C₆₋₆₀ aryl group (i.e., as a pendant group to the polymer backbone).

In some embodiments, the first polymer may comprise the first structural unit derived from an N-(alkoxymethyl) (meth)acrylic amide monomer, and the photoresist underlayer composition may further include a second polymer that comprises the second structural unit. For example, the second polymer may include the second structural unit that includes a C₃₋₆₀ heterocycloalkyl group and the crosslinkable group. The C₃₋₆₀ heterocycloalkyl group can be further substituted with other substituent groups besides the crosslinkable group, or may be unsubstituted beyond including the crosslinkable group. Exemplary further substituents may include one or more of substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₁₋₃₀ heterocycloalkyl, substituted or unsubstituted C₂₋₃₀ alkenyl, substituted or unsubstituted C₂₋₃₀ alkynyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ alkylheteroaryl, or substituted or unsubstituted C₄₋₃₀ heteroarylalkyl. The crosslinkable group may be connected directly to an atom of the C₃₋₆₀ heterocycloalkyl group (i.e., via a single bond), or the crosslinkable group may be linked to the C₃₋₆₀ heterocycloalkyl group via a divalent linking group (i.e., as a pendant group to the polymer backbone).

The first structural unit is derived from an N-(alkoxymethyl) (meth)acrylic amide monomer, which may be represented Formula (1):

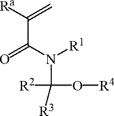

In Formula (1), R^{a} is hydrogen, fluorine, cyano, or substituted or unsubstituted C₁₋₁₀ alkyl. Preferably, R^{a} is hydrogen, fluorine, cyano, or substituted or unsubstituted C₁₋₅ alkyl, typically methyl.

In Formula (1), R¹ is hydrogen, or substituted or unsubstituted C₁₋₁₀ alkyl. Typically, R¹ is hydrogen or methyl. In some embodiments, R¹ is not hydrogen.

In Formula (1), R² and R³ are each independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ heteroarylalkyl, or substituted or unsubstituted C₄₋₃₀ alkylheteroaryl. Preferably, R² and R³ are each independently hydrogen or substituted or unsubstituted C₁₋₁₀ alkyl, typically methyl. In some aspects, at least one of R² and R³ is hydrogen, and for example, R² and R³ both may be hydrogen. R² and R³ optionally may form a ring via a single bond or a divalent linking group, wherein the ring is substituted or unsubstituted.

Each of R² and R³ optionally further comprises a divalent linking group as part of their structure. For example, each of R² and R³ optionally may further include as part of their structure one or more divalent linking groups selected from —O—, —C(O)—, —C(O)O—, —S—, —S(O)₂—, —N(R)—, or —C(O)N(R′)—, wherein R′ may be hydrogen, substituted or unsubstituted C₁₋₂₀ alkyl, substituted or unsubstituted C₃₋₂₀ cycloalkyl, or substituted or unsubstituted C₃₋₂₀ heterocycloalkyl.

R⁴ is hydrogen, substituted or unsubstituted C₁₋₂₀ alkyl, substituted or unsubstituted C₃₋₂₀ cycloalkyl, substituted or unsubstituted C₂₋₂₀ heterocycloalkyl, substituted or unsubstituted C₆₋₂₄ aryl, substituted or unsubstituted C₇₋₂₅ arylalkyl, substituted or unsubstituted C₇₋₂₅ alkylaryl, substituted or unsubstituted C₃₋₂₀ heteroaryl, substituted or unsubstituted C₄₋₂₀ heteroarylalkyl, or substituted or unsubstituted C₄₋₂₀ alkylheteroaryl.

One of R² or R³ optionally may form a heterocyclic ring together with R⁴ via a single bond or a divalent linking group, wherein the heterocyclic ring is substituted or unsubstituted.

Exemplary N-(alkoxymethyl) (meth)acrylic amide monomers may include one or more of the following:

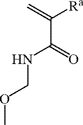

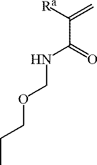

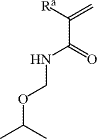

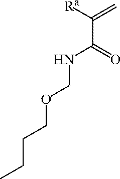

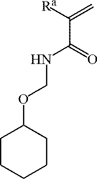

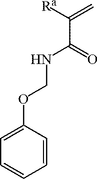

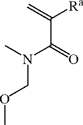

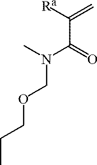

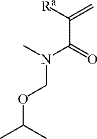

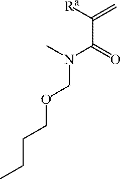

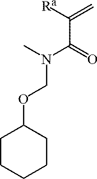

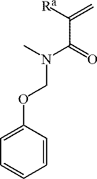

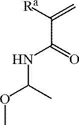

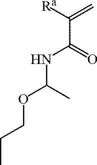

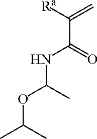

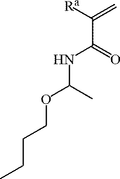

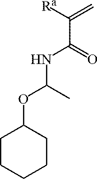

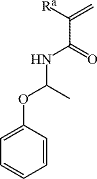

wherein R^{a} is a defined in Formula (1).

The first structural unit derived from the N-(alkoxymethyl) (meth)acrylic amide monomer is typically present in the first polymer in an amount from 5 to 100 mole percent (mol%), more typically from 5 to 75 mol%, still more typically from 5 to 50 mol%, based on total structural units in the first polymer.

The second structural unit may include an aromatic group and may be derived from a monomer of Formula (2):

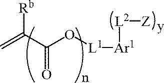

Wherein each R^{b} may be hydrogen, fluorine, cyano, or substituted or unsubstituted C₁₋₁₀ alkyl. Preferably, R^{b} may be hydrogen, fluorine, or substituted or unsubstituted C₁₋₅ alkyl, typically methyl.

In Formula (2), n is 0 or 1. It is to be understood that when n is 0, then L¹ is bonded directly to the carbon atom of the alkenyl group in Formula (2).

In Formula (2), L¹ represents a single bond or a divalent linking group. For example, L¹ may be a divalent linking group chosen from optionally substituted aliphatic, such as C₁₋₆ alkylene or C₃₋₂₀ cycloalkylene, and aromatic hydrocarbons, and combinations thereof, optionally with one or more linking moieties chosen from —O—, —C(O)—, —C(O)O—, —S—, —S(O)₂—, —NR¹⁰²—, or —C(O)N(R¹⁰²)—, wherein R¹⁰² is chosen from hydrogen and optionally substituted C₁₋₁₀ alkyl.

When n is 0 and L¹ is a single bond, it is to be understood that the group Ar¹ is bonded directly to the carbon atom of the alkenyl group in Formula (2).

In Formula (2), Ar¹ is a substituted or unsubstituted C₆₋₆₀ aryl group, typically a substituted or unsubstituted C₆₋₁₄ aryl group.

In Formula (2), each L² is independently a single bond or a divalent linking group. Exemplary divalent linking groups for L² include one or more of substituted or unsubstituted C₁₋₃₀ alkylene, substituted or unsubstituted C₁₋₃₀ heteroalkylene, substituted or unsubstituted C₃₋₃₀ cycloalkylene, substituted or unsubstituted C₃₋₃₀ heterocycloalkylene, substituted or unsubstituted C₆₋₃₀ arylene, substituted or unsubstituted C₃₋₃₀ heteroarylene, —O—, —C(O)—, —C(O)O—, —S—, —S(O)₂—, —N(R¹⁰³)—, or —C(O)N(R¹⁰⁴)—, wherein R¹⁰³ and R¹⁰⁴ may be each independently hydrogen, substituted or unsubstituted C₁₋₂₀ alkyl, substituted or unsubstituted C₃₋₂₀ cycloalkyl, or substituted or unsubstituted C₃₋₂₀ heterocycloalkyl.

In Formula (2), each Z is independently a crosslinkable group. Preferably, each Z is interpedently hydroxyl, carboxyl, thiol, amino, amido, epoxy, or lactone, typically hydroxyl, thiol, or epoxy, and more typically hydroxyl.

In Formula (2), y is an integer from 1 to 3, preferably y is an integer from 1 to 2, and typically y is 1.

Non-limiting examples of monomers of Formula (2) may include the following:

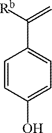

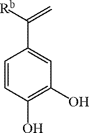

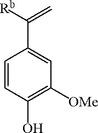

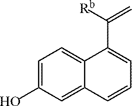

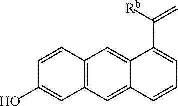

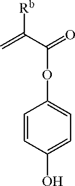

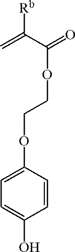

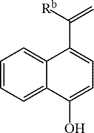

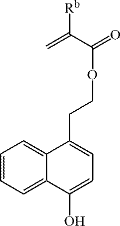

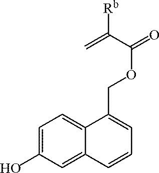

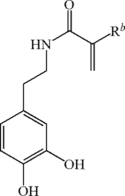

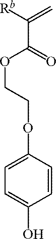

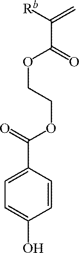

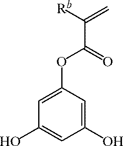

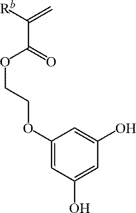

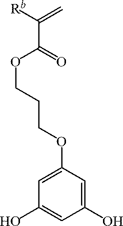

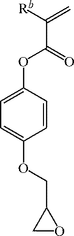

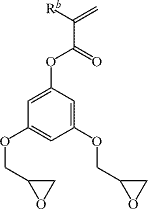

wherein R^{b} is as defined in Formula (2).

The polymer comprising the second structural unit may include a repeating unit derived from a monomer of Formula 2 in an amount from 2 to 100 mol%, typically 10 to 100 mol%, more typically 50 to 100 mol% based on total repeating units in the polymer. When the first polymer includes the second structural unit, the second structural unit is typically present in the first polymer in an amount from 5 to 100 mol%, more typically from 5 to 75 mol%, still more typically from 5 to 50 mol%, based on total structural units in the first polymer.

Non-limiting exemplary first polymers of the present invention include one or more of the following:

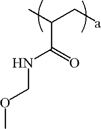

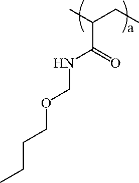

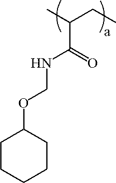

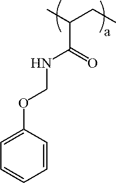

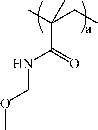

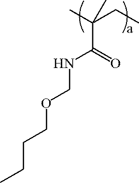

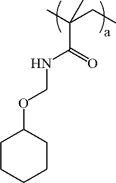

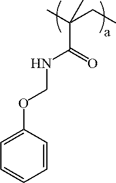

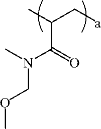

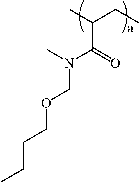

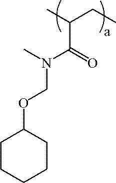

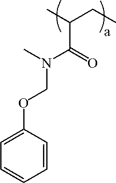

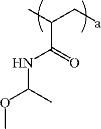

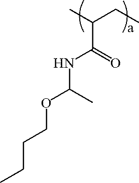

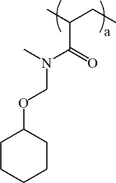

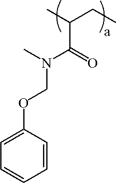

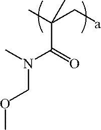

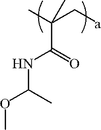

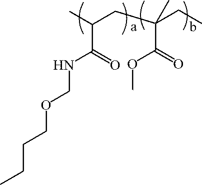

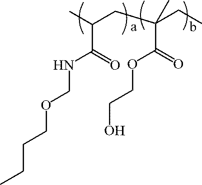

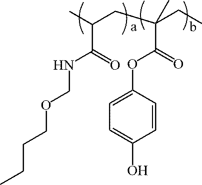

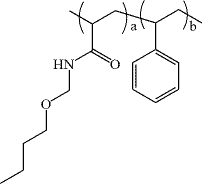

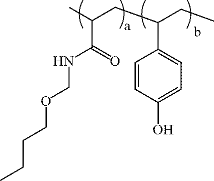

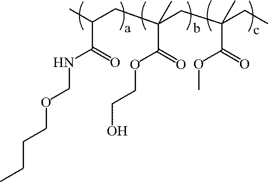

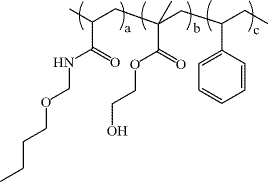

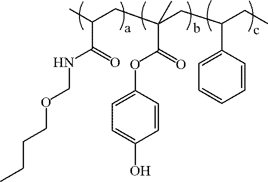

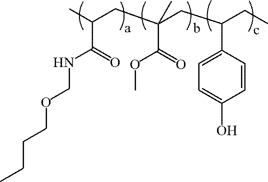

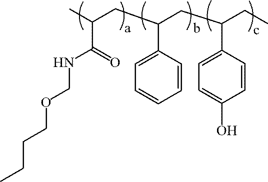

wherein a, b, c, and d represent the mole fractions for the respective repeating units of the first polymer.

In some embodiments, the second structural unit may include a heterocyclic group and may be a crosslinkable polyester polymer that includes a crosslinkable group. For example, a second polymer may include an isocyanurate repeating unit and a crosslinkable group. In some aspects, the crosslinkable group may be selected from hydroxyl, carboxyl, thiol, amino, epoxy, alkoxy, amido, vinyl, or a combination thereof.

It is preferred that the second polymer, when used, is a polymer including one or more isocyanurate repeating units derived from a monomer of Formula (3):

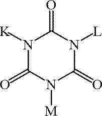

In Formula (3), K, L, and M are each independently a linear or branched C₁₋₁₀ hydrocarbon group, a C₁₋₁₀ alkoxycarbonyl group, a C₁₋₁₀ alkanoyloxy group, each of which is optionally substituted with a carboxylic acid group, or a linear or branched C₁₋₁₀ hydroxyalkyl group optionally substituted with a C₁₋₅ alkoxycarbonyl group or a C₁₋₅ substituted alkoxy group.

In Formula (3), for K, L, and M, each of the C₁₋₁₀ hydrocarbon group, the C₁₋₁₀ alkoxycarbonyl group, the C₁₋₁₀ alkanoyloxy group, and the C₁₋₁₀ hydroxyalkyl group may be optionally substituted with at least one of a halogen, an amino group, a thiol group, an epoxy group, an amido group, a C₁₋₅ alkyl group, a C₃₋₈ cycloalkyl group, a C₃₋₂₀ heterocycloalkyl group, a C₂₋₅ alkenyl group, a C₁₋₅ alkoxy group, a C₂₋₅ alkenoxy group, a C₆₋₁₂ aryl group, a C₆₋₁₂ aryloxy group, a C₇₋₁₃ alkylaryl group, or C₇₋₁₃ alkylaryloxy group. The C₃₋₈ cycloalkyl group and the C₃₋₂₀ heterocycloalkyl group may be optionally substituted on at least one ring carbon atom with an oxo group (═O). At least one hydrogen atom of the first polymer derived from the monomer of formula (2) is substituted with a functional group independently chosen from hydroxyl, carboxyl, thiol, amino, epoxy, alkoxy, amido, vinyl, or a combination thereof. Of these, hydroxyl, carboxyl, or alkoxy are preferred.

In some embodiment, the second structural unit may include a heterocyclic group comprising a substituted cyanurate structural unit that is derived from a compound represented by Formula (4), Formula (5), or a combination thereof:

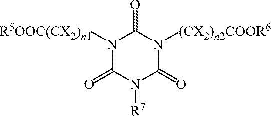

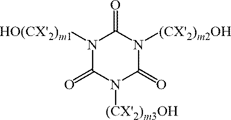

In Formulae (4) and (5), R⁵ and R⁶ are each independently hydrogen, substituted or unsubstituted C₁₋₃₀ alkyl, substituted or unsubstituted C₃₋₃₀ cycloalkyl, substituted or unsubstituted C₃₋₃₀ heterocycloalkyl, substituted or unsubstituted C₆₋₃₀ aryl, or substituted or unsubstituted C₃₋₃₀ heteroaryl.

In Formulae (4) and (5), R⁷ is hydrogen, —C(O)OH, substituted or unsubstituted C₁₋₃₀ alkyl, substituted or unsubstituted C₂₋₃₀ alkenyl, substituted or unsubstituted C₂₋₃₀ alkynyl, substituted or unsubstituted C₂₋₃₀ alkanoyl, substituted or unsubstituted C₁₋C₃₀ alkoxy, substituted or unsubstituted C₁-C₃₀ alkylthio, substituted or unsubstituted C₁₋C₃₀ alkylsulfinyl, substituted or unsubstituted C₁₋C₃₀ alkylsulfonyl, substituted or unsubstituted C₂-C₃₀ alkoxycarbonyl, substituted or unsubstituted C₃₋₂₀ cycloalkenyl, substituted or unsubstituted C₃₋₂₀ heterocycloalkenyl, substituted or unsubstituted C₆-C₃₀ aryl, substituted or unsubstituted C₇-C₃₀ alkylaryl, substituted or unsubstituted C₇-C₃₀ arylalkyl, substituted or unsubstituted C₃₋₃₀ heteroaryl, substituted or unsubstituted C₄₋₃₀ alkylheteroaryl, or substituted or unsubstituted C₄₋₃₀ heteroarylalkyl.

In Formulae (4) and (5), each X and X′ is independently hydrogen, or substituted or unsubstituted C₁₋₁₀ alkyl. Preferably, each X and X′ is hydrogen.

In Formulae (4) and (5), n1, n2, m1, m2, and m3 are each independently an integer from 1 to 10. Preferably, each of n1, n2, m1, m2, and m3 independently may be an integer from 1 to 4, typically 1 or 2.

The second polymer including the second structural unit comprising a substituted cyanurate structural unit may be formed by conventional polycondensation techniques such as for example described in Pappas et al., “Organic Coatings, Science and Technology,” pp 246-257 (John Wiley & Sons, 1999, 2 ed.) and references therein and/or in Houben-Weyl, “Methoden der Organischen Chemie, Band E20, Makromolekulare Soffe, Polyester,” pp 1405-1429. (Georg Thieme Verlag, Stuttgart 1987) and references therein. In one aspect, a diol or polyol and a di-carboxylic acid or polycarboxylic acid are charged into a conventional polymerization vessel and reacted at from about 100 to 280° C. for several hours. Optionally, an esterification catalyst may be used to decrease the reaction time. It is also understood that an esterifiable derivative of a polycarboxylic acid, such as a dimethyl ester or anhydride of a polycarboxylic acid, can be used to prepare the polyester. Exemplary polyols and polycarboxylic acids include isocyanurate polyols and isocyanurate polycarboxylic acids. The polyester polymers can be linear or branched.

Suitable dicarboxylic acids or polycarboxylic acids, or their corresponding alkyl esters, that may be used to form the second polymer include saturated as well as unsaturated dicarboxylic acids such as, for example, isophthalic acid, maleic acid, maleic anhydride, malonic acid, fumaric acid, succinic acid, succinic anhydride, glutaric acid, adipic acid, 2-methyl-1,6-hexanoic acid, pimelic acid, suberic acid, dodecanedioic acids, phthalic acid, phthalic anhydride, 5-tert butyl isophthalic acid, tetrahydrophthalic anhydride, hexahydrophthalic acid, hexahydrophthalic anhydride, endomethylenetetrahydrophthalic anhydride, azelaic acid, sebacic acid, tetrachlorophthalic anhydride, chlorendic acid, isophthalic acid, trimellitic anhydride, terephthalic acid, naphthalene dicarboxylic acid, cyclohexane-dicarboxylic acid, dimer fatty acid, or anhydrides of any of these acids, or combinations thereof.

Suitable diols and polyols include, but are not limited to, ethylene glycol, diethylene glycol, triethylene glycol and higher polyethylene glycols, propylene glycol, dipropylene glycol, tripropylene glycol and higher polypropylene glycols, 1,3-propanediol, 1,4-butanediol and other butanediols, 1,5-pentanediol and other pentane diols, hexanediols, decanediols, and dodecanediols, glycerol, trimethylolpropane, trimethylolethane, neopentyl glycol, pentaerythritol, cyclohexanedimethanol, dipentaerythtritol, 1, 2-methyl-1,3-propanediol, 1,4-benzyldimethanol, 2,4-dimethyl-2-ethylhexane-1,3-diol, isopropylidene bis (p-phenylene-oxypropanol-2), 4,4′-dihydroxy-2,2′-diphenylpropane, 1,3-cyclohexanedimethanol, 1,4-cyclohexanedimethanol (or mixtures of 1,3 and 1,4 cyclohexanedimethanol, may be cis or trans), sorbitol, or the like, or combinations thereof.

When the second polymer includes the second structural unit that includes a heterocyclic group, the second structural unit is typically present in the second polymer in an amount from 5 to 100 mol%, more typically from 5 to 50 mol%, still more typically from 5 to 30 mol%, based on total structural units in the second polymer. For example, the second structural unit may include a heterocyclic group comprising from 5 to 50 mol% or from 5 to 30 mol% of a substituted cyanurate structural unit that is derived from a compound represented by Formula (4), Formula (5), or a combination thereof.

It is to be understood that the polymers described herein, including the first polymer and the second polymer, each independently may optionally include one or more additional repeating unit(s) different from the repeating units described above. The additional repeating units may include, for example, one or more additional units for purposes of adjusting properties of the photoresist underlayer composition, such as etch rate and solubility. Exemplary additional units may include one or more of (meth)acrylate, vinyl ether, vinyl ketone, and vinyl ester. The one or more additional repeating units if present in the polymer is typically used in an amount of up to 99 mol%, and typically from 3 to 80 mol%, based on total repeating units of the respective polymer.

The polymers of the invention may have a weight average molecular weight (M_{w}) of 1,000 to 10,000,000 grams per mole (g/mol), more typically 2,000 to 10,000 g/mol, and a number average molecular weight (Mₙ) of 500 to 1,000,000 g/mol. Molecular weights (either M_{w} or Mₙ) are suitably determined by gel permeation chromatography (GPC) using polystyrene standards.

Suitable polymers of the present invention can be readily prepared based on and by analogy with the procedures described in the examples of the present application, which are readily understood by those of ordinary skill in the art. For example, one or more monomers corresponding to the repeating units described herein may be combined, or fed separately, using suitable solvent(s) and initiator, and polymerized in a reactor. The monomer composition may further include additives, such as a solvent, a polymerization initiator, a curing catalyst (i.e., the acid catalyst), and the like. For example, the polymer may be obtained by polymerization of the respective monomers under any suitable conditions, such as by heating at an effective temperature, irradiation with activating radiation at an effective wavelength, or a combination thereof.

The photoresist underlayer composition may further include one or more polymers (“additional polymers”) in addition to the polymers described above. For example, the photoresist underlayer composition may further include an additional polymer as described above but different in composition. Additionally, or alternatively, the one or more additional polymers can include those well known in the art, for example, one or more polymers selected from polyacrylates, polyvinylethers, polyesters, polynorbornenes, polyacetals, polyethylene glycols, polyamides, polyacrylamides, polyphenols, novolacs, styrenic polymers, polyvinyl alcohols, copolymers thereof, and combination thereof.

The photoresist underlayer composition further includes a thermal acid generator (TAG) compound to aid in the curing of the photoresist underlayer composition, for example after the photoresist underlayer composition has been applied to a surface. The inventive photoresist underlayer compositions may include any suitable TAG that causes curing of the photoresist underlayer composition on the surface of a substrate.

Exemplary thermal acid generators include, without limitation, amine blocked strong acids, such as amine blocked sulfonic acids such as amine blocked dodecylbenzenesulfonic acid. It will also be appreciated by those skilled in the art that certain photoacid generators are able to liberate acid upon heating and may function as thermal acid generators.

Suitable TAG compounds may include, for example, nitrobenzyl tosylates, such as 2-nitrobenzyl tosylate, 2,4-dinitrobenzyl tosylate, 2,6-dinitrobenzyl tosylate, 4-nitrobenzyl tosylate; benzenesulfonates such as 2-trifluoromethyl-6-nitrobenzyl 4-chlorobenzenesulfonate, 2-trifluoromethyl-6-nitrobenzyl 4-nitro benzenesulfonate; phenolic sulfonate esters such as phenyl, 4-methoxybenzenesulfonate; alkyl ammonium salts of organic acids, such as triethylammonium salt of 10-camphorsulfonic acid, trifluoromethylbenzenesulfonic acid, perfluorobutane sulfonic acid; and particular onium salts. A variety of aromatic (anthracene, naphthalene, or benzene derivatives) sulfonic acid amine salts can be employed as the TAG, including those disclosed in U.S. Pat. Nos. 3,474,054, 4,200,729, 4,251,665 and 5,187,019. Examples of TAGs include those sold by King Industries, Norwalk, Conn. USA under NACURE, CDX and K-PURE names, for example, NACURE 5225, CDX-2168E, K-PURE 2678 and KPURE 2700. One or more of such TAGs can be used.

The amount of the TAG compound useful in the present compositions may be, for example, from 0.01 to 15 wt%, and typically from 0.01 to 10 wt%, based on total solids of the photoresist underlayer composition.

In some embodiments, the photoresist underlayer composition may further include a photoacid generator (PAG). Suitable PAGs include, for example: onium salts, for example, triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate; nitrobenzyl derivatives, for example, 2-nitrobenzyl-p-toluenesulfonate, 2,6-dinitrobenzyl-p-toluenesulfonate, and 2,4-dinitrobenzyl-p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane; glyoxime derivatives, for example, bis-O-(p-toluenesulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester; and halogen-containing triazine compounds, for example, 2-(4-methoxyphenyl)-4,6-bis(trichloromethyl)-1,3,5-triazine, and 2-(4-methoxynaphthyl)-4,6-bis(trichloromethyl)-1,3,5-triazine. One or more of such PAGs can be used.

In some aspects, the photoresist underlayer composition does not include a photoacid generator. Accordingly, in these embodiments the photoresist underlayer composition may be substantially free of a PAG compound.

The photoresist underlayer composition may further include one or more crosslinking agents, for example a crosslinking agent that includes non-epoxy crosslinkers. Any suitable crosslinking agent may be further used in the present coating compositions, provided that such crosslinking agent has at least 2, and preferably at least 3, moieties capable of reacting with functional groups in the photoresist underlayer composition. Exemplary crosslinking agents may include novolac resins, melamine compounds, guanamine compounds, isocyanate-containing compounds, benzocyclobutenes, benzoxazines, and the like, and typically any of the foregoing having 2 or more, more typically 3 or more substituents selected from methylol, C₁₋₁₀ alkoxymethyl, and C₂₋₁₀ acyloxymethyl. Examples of suitable crosslinking agents include those shown below:

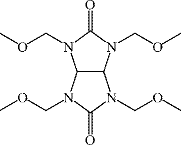

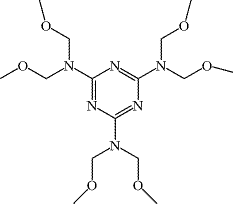

The additional crosslinking agents are well-known in the art and are commercially available from a variety of sources. When present, the amount of such additional crosslinking agents useful in the present photoresist underlayer compositions may be, for example, from 0.01 to 30 wt%, and preferably from 0.01 to 20 wt%, based on total solids of the photoresist underlayer composition.

The photoresist underlayer composition may include one or more optional additives including, for example, surfactants, antioxidant, or the like, or a combination thereof. When present, each optional additive may be used in the photoresist underlayer composition in minor amounts such as from 0.01 to 10 wt%, based on total solids of the photoresist underlayer composition.

Typical surfactants include those which exhibit an amphiphilic nature, meaning that they may be both hydrophilic and hydrophobic at the same time. Amphiphilic surfactants possess a hydrophilic head group or groups, which have a strong affinity for water and a long hydrophobic tail, which is organophilic and repels water. Suitable surfactants may be ionic (i.e., anionic, or cationic) or nonionic. Further examples of surfactants include silicone surfactants, poly(alkylene oxide) surfactants, and fluorochemical surfactants. Suitable non-ionic surfactants include, but are not limited to, octyl and nonyl phenol ethoxylates such as TRITON X-114, X-100, X-45, X-15 and branched secondary alcohol ethoxylates such as TERGITOL TMN-6 (The Dow Chemical Company, Midland, Mich. USA). Still further exemplary surfactants include alcohol (primary and secondary) ethoxylates, amine ethoxylates, glucosides, glucamine, polyethylene glycols, poly(ethyleneglycol-co-propylene glycol), or other surfactants disclosed in McCutcheon’s Emulsifiers and Detergents, North American Edition for the Year 2000 published by Manufacturers Confectioners Publishing Co. of Glen Rock, N.J. Nonionic surfactants that are acetylenic diol derivatives also may be suitable. Such surfactants are commercially available from Air Products and Chemicals, Inc. of Allentown, Pa. and sold under the trade names of SURFYNOL and DYNOL. Additional suitable surfactants include other polymeric compounds such as the tri-block EO-PO-EO co-polymers PLURONIC 25R2, L121, L123, L31, L81, L101, and P123 (BASF, Inc.).

Suitable antioxidants include, for example, phenol-based antioxidants, antioxidants composed of an organic acid derivative, sulfur-containing antioxidants, phosphorus-based antioxidants, amine-based antioxidants, antioxidant composed of an amine-aldehyde condensate and antioxidants composed of an amine-ketone condensate. Examples of the phenol-based antioxidant include substituted phenols such as 1-oxy-3-methyl-4-isopropylbenzene, 2,6-di-tert-butylphenol, 2,6-di-tert-butyl-4-ethylphenol, 2,6-di-tert-butyl-4-methylphenol, 4-hydroxymethyl-2,6-di-tert-butylphenol, butyl.hydroxyanisole, 2-(1-methylcyclohexyl)-4,6-dimethylphenol, 2,4-dimethyl-6-tert-butylphenol, 2-methyl-4,6-dinonylphenol, 2,6-di-tert-butyl-α-dimethylamino-p-cresol, 6-(4-hydroxy-3,5-di-tert-butyl.anilino)2,4-bis.octyl-thio-1,3,5-triazine, n-octadecyl-3-(4′-hydroxy-3′,5′-di-tert-butyl.phenyl)propionate, octylated phenol, aralkyl-substituted phenols, alkylated p-cresol and hindered phenol; bis-, tris- and poly-phenols such as 4,4′-bisphenol, 4,4′-methylene-bis-(dimethyl-4,6-phenol), 2,2′-methylene-bis-(4-methyl-6-tert-butylphenol), 2,2′-methylene-bis-(4-methyl-6-cyclohexylphenol), 2,2′-methylene-bis-(4-ethyl-6-tert-butylphenol), 4,4′-methylene-bis-(2,6-di-tert-butylphenol), 2,2′-methylene-bis-(6-α-methyl-benzyl-p-cresol),methylene-crosslinked polyvalent alkylphenol, 4,4′-butylidene-bis-(3-methyl-6-tert-butylphenol), 1,1-bis-(4-hydroxyphenyl)-cyclohexane, 2,2′-dihydroxy-3,3′-di-(α-methylcyclohexyl)-5,5′-dimethyl.diphenylmethane, alkylated bisphenol, hindered bisphenol, 1,3,5-trimethyl-2,4,6-tris(3,5-di-tert-butyl-4-hydroxybenzyl)benzene, tris-(2-methyl-4-hydroxy-5-tert-butylphenyl)butane, and tetrakis-[methylene-3-(3′,5′-di-tert-butyl-4′-hydroxyphenyl)propionate]methane. Suitable antioxidants are commercially available, for example, Irganox™ antioxidants (Ciba Specialty Chemicals Corp.).

The photoresist underlayer composition includes a solvent. The solvent component may be a single solvent or may include a mixture of two or more distinct solvents. Suitably, each of the multiple solvents may be miscible with each other. Suitable solvents include, for example, one or more oxyisobutyric acid esters, particularly methyl-2-hydroxyisobutyrate, 2-hydroxyisobutyric acid, and ethyl lactate; one or more of glycol ethers, particularly 2-methoxyethyl ether (diglyme), ethylene glycol monomethyl ether, and propylene glycol monomethyl ether; one or more solvents that have both ether and hydroxy moieties, particularly methoxy butanol, ethoxy butanol, methoxy propanol, and ethoxy propanol; one or more alkyl esters, particularly methyl cellosolve acetate, ethyl cellosolve acetate, propylene glycol monomethyl ether acetate, and dipropylene glycol monomethyl ether acetate and other solvents such as one or more dibasic esters; and/or other solvents such as one or more of propylene carbonate and gamma-butyro lactone.

The desired total solids of the photoresist underlayer composition will depend on factors such as the desired final layer thickness. Typically, the total solids of the photoresist underlayer composition may be from 0.1 to 20 wt%, for example, from 0.1 to 10 wt%, more typically, from 0.1 to 5 wt%, based on the total weight of the photoresist underlayer composition.

The photoresist underlayer composition may be prepared following known procedures. For example, the photoresist underlayer composition may be prepared by combining the first material, the second material, the additive, the solvent, and any optional components, in any order. The photoresist underlayer composition may be used as is, or may be subjected to purification or dilution prior to being coated on the substrate. Purification may involve, for example, one or more of centrifugation, filtration, distillation, decantation, evaporation, treatment with ion exchange beads, and the like.

The patterning methods of the present invention comprise applying a layer of the photoresist underlayer composition over a substrate; curing the applied photoresist underlayer composition to form a photoresist underlayer; and forming a photoresist layer over the photoresist underlayer. The method may further include patterning the photoresist layer and transferring a pattern from the patterned photoresist layer to the photoresist underlayer and to a layer below the photoresist underlayer. In some embodiments, the method may further include the steps of pattern-wise exposing the photoresist layer to activating radiation; and developing the exposed photoresist layer to provide a resist relief image. In some aspects, the method may further include forming a silicon-containing layer, an organic antireflective coating layer, or a combination thereof, above the photoresist underlayer prior to forming the photoresist layer. In some aspects, the method may further include transferring the pattern to the silicon-containing layer, the organic antireflective coating layer, or the combination thereof, after developing an exposed photoresist layer and before the step transferring the pattern to the photoresist underlayer.

A wide variety of substrates may be used in the patterning methods, with electronic device substrates being typical. Suitable substrates include, for example, packaging substrates such as multichip modules; flat panel display substrates; integrated circuit substrates; substrates for light emitting diodes (LEDs) including organic light emitting diodes (OLEDs); semiconductor wafers; polycrystalline silicon substrates; and the like. Suitable substrates may be in the form of wafers such as those used in the manufacture of integrated circuits, optical sensors, flat panel displays, integrated optical circuits, and LEDs. As used herein, the term “semiconductor wafer” is intended to encompass “an electronic device substrate,” “a semiconductor substrate,” “a semiconductor device,” and various packages for various levels of interconnection, including a single-chip wafer, multiple-chip wafer, packages for various levels, or other assemblies requiring solder connections. Such substrates may be any suitable size. Typical wafer substrate diameters are 200 to 300 mm, although wafers having smaller and larger diameters may be suitably employed according to the present invention. As used herein, the term “semiconductor substrate” includes any substrate having one or more semiconductor layers or structures which may optionally include active or operable portions of semiconductor devices. A semiconductor device refers to a semiconductor substrate upon which at least one microelectronic device has been or is being batch fabricated.

The substrates are typically composed of one or more of silicon, polysilicon, silicon oxide, silicon nitride, silicon oxynitride, silicon germanium, gallium arsenide, aluminum, sapphire, tungsten, titanium, titanium-tungsten, nickel, copper, and gold. The substrate may include one or more layers and patterned features. The layers may include, for example, one or more conductive layers such as layers of aluminum, copper, molybdenum, tantalum, titanium, tungsten, alloys, nitrides, or silicides of such metals, doped amorphous silicon or doped polysilicon, one or more dielectric layers such as layers of silicon oxide, silicon nitride, silicon oxynitride, or metal oxides, semiconductor layers, such as single-crystal silicon, and combinations thereof. In some aspects, the substrate includes titanium nitride. The layers can be formed by various techniques, for example, chemical vapor deposition (CVD) such as plasma-enhanced CVD (PECVD), low-pressure CVD (LPCVD) or epitaxial growth, physical vapor deposition (PVD) such as sputtering or evaporation, or electroplating.

It may be desired in certain patterning methods of the invention to provide one or more lithographic layers such as a hardmask layer, for example, a spin-on-carbon (SOC), amorphous carbon, or metal hardmask layer, a CVD layer such as a silicon nitride (SiN) layer, silicon oxide (SiO) layer, or silicon oxynitride (SiON) layer, an organic or inorganic BARC layer, or a combination thereof, on an upper surface of the substrate prior to forming the photoresist underlayer of the invention. Such layers, together with a layer of the photoresist underlayer composition of the invention and photoresist layer, form a lithographic material stack. Typical lithographic stacks which may be used in the patterning methods of the invention include, for example, the following: SOC layer/underlayer/photoresist layer; SOC layer/SiON layer/underlayer/photoresist layer; SOC layer/ SiARC layer/underlayer/photoresist layer; SOC layer/metal hardmask layer/underlayer/photoresist layer; amorphous carbon layer/underlayer/photoresist layer; and amorphous carbon layer/SiON layer/underlayer/photoresist layer.

It is to be understood that the “photoresist underlayer,” as used herein, refers to the one or more layers that are disposed between the substrate and the photoresist layer (i.e., “above the substrate”). Accordingly, the inventive coated underlayer (i.e., a layer of the photoresist underlayer composition) may be used alone as a photoresist underlayer, or the inventive coated underlayer (i.e., a layer of the photoresist underlayer composition) may be used in conjunction with other underlayers, including those as described herein.

The photoresist underlayer composition may be coated on the substrate by any suitable means, such as spin-coating, slot-die coating, doctor blading, curtain-coating, roller-coating, spray-coating, dip-coating, and the like. In the case of a semiconductor wafer, spin-coating is preferred. In a typical spin-coating method, the present compositions are applied to a substrate which is spinning at a rate of 500-4000 revolutions per minute (rpm) for a period of 15-90 seconds to obtain a desired layer of the condensed polymer on the substrate. It will be appreciated by those skilled in the art that the thickness of the coated layer may be adjusted by changing the spin speed, as well as the solids content of the composition. An underlayer formed from the photoresist underlayer composition typically has a dried layer thickness from 1-500 nanometers (nm), more typically from 1-100 nm.

The coated photoresist underlayer composition is optionally softbaked at a relatively low temperature to remove any solvent and other relatively volatile components. Typically, the substrate is baked at a temperature of less than or equal to 150° C., preferably from 60-125° C., and more preferably from 90-115° C. The baking time is typically from 10 seconds to 10 minutes, preferably from 30 seconds to 5 minutes, and more preferably from 6-90 seconds. When the substrate is a wafer, such baking step may be performed by heating the wafer on a hot plate. Such soft-baking step may be performed as part of the curing of the coating layer, or may be omitted altogether.

The photoresist underlayer composition is then cured to form a coated underlayer. The coating composition should be sufficiently cured such that the coated underlayer film does not intermix, or minimally intermixes, with another underlayer component or the photoresist layer to be formed above the underlayer. The coated composition may be cured in an oxygen-containing atmosphere, such as air, or in an inert atmosphere, such as nitrogen and under conditions, such as heating, sufficient to provide a cured coating layer. This curing step is preferably conducted on a hot plate-style apparatus, although oven curing may be used to obtain equivalent results. Typically, the curing may be conducted at a temperature of 150° C. or greater, or from 150-450° C. It is more preferred that the curing temperature is 180° C. or greater, or from 200-400° C. The curing time is typically from 10 seconds to 10 minutes, or from 30 seconds to 5 minutes, or from 45 seconds to 2 minutes, or from 45-90 seconds.

Optionally, a ramped or a multi-stage curing process may be used. A ramped bake typically begins at a relatively low (e.g., ambient) temperature that is increased at a constant or varied ramp rate to a higher target temperature. A multi-stage curing process involves curing at two or more temperature plateaus, typically a first stage at a lower bake temperature and one or more additional stages at a higher temperature. Conditions for such ramped or multi-stage curing processes are known to those skilled in the art, and may allow for omission of a preceding softbake process.

After curing of the applied photoresist underlayer composition, a photoresist layer is formed over the applied photoresist underlayer. As noted above, other intervening layers may be applied between the applied photoresist underlayer and the overcoated photoresist layer. In some aspect, the method may further include forming a silicon-containing layer, an organic antireflective coating layer, or a combination thereof, over the applied photoresist underlayer prior to forming the photoresist layer.

A wide variety of photoresists may be suitably used in the methods of the invention and are typically positive-tone materials. The particular photoresists to be used will depend on the exposure wavelength used and generally comprise an acid-sensitive matrix polymer, a photoactive component such as a photoacid generator, a solvent, and optional additional components. Suitable photoresists are known to those skilled in the art and are commercially available, for example, various photoresist materials in the UV™ and EPIC™ product families from DuPont Electronics & Industrial. The photoresist can be applied to the substrate by known coating techniques such as described above with reference to the underlayer composition, with spin-coating being typical. A typical thickness for the photoresist layer is from 10-300 nm. The photoresist layer is typically next softbaked to minimize the solvent content in the layer, thereby forming a tack-free coating and improving adhesion of the layer to the substrate. The softbake can be conducted on a hotplate or in an oven, with a hotplate being typical. Typical photoresist softbakes are conducted at a temperature from 70-150° C., and a time from 30-90 seconds.

The photoresist layer is then exposed to activating radiation through a photomask to create a difference in solubility between exposed and unexposed regions. References herein to exposing a photoresist composition to radiation that is activating for the composition indicates that the radiation is capable of forming a latent image in the photoresist composition. The photomask has optically transparent and optically opaque regions corresponding to regions of the resist layer to be exposed and unexposed, respectively, by the activating radiation. The exposure wavelength is typically sub-400 nm, and more typically, sub-300 nm, such as 248 nm (KrF), 193 nm (ArF), or an EUV wavelength (e.g., 13.5 nm). In a preferred aspect, the exposure wavelength is 193 nm or an EUV wavelength. The exposure energy is typically from 10 to 100 millijoules per square centimeter (mJ/cm²), depending, for example, on the exposure tool and the components of the photosensitive composition.

Following exposure of the photoresist layer, a post-exposure bake (PEB) is typically performed. The PEB can be conducted, for example, on a hotplate or in an oven. The PEB is typically conducted at a temperature from 70 to 150° C., and a time from 30 to 90 seconds. A latent image defined by the boundary between polarity-switched and unswitched regions (corresponding to exposed and unexposed regions, respectively) is thereby formed. The photoresist layer is next developed to remove the exposed regions of the layer, leaving the unexposed regions forming a patterned photoresist layer. The developer is typically an aqueous alkaline developer, for example, a tetra-alkyl ammonium hydroxide solution such as a tetramethylammonium hydroxide (TMAH) solution, typically a 0.26 Normality (N) (2.38 wt%) solution of TMAH. The developer may be applied by known techniques, for example, spin-coating or puddle coating.

The pattern of the photoresist layer can be transferred to one or more underlying layers including the coated underlayer and to the substrate by appropriate etching techniques, such as by plasma etching using appropriate gas species for each layer being etched. Depending on the number of layers and materials involved, pattern transfer may include multiple etching steps using different etching gases. The patterned photoresist layer, the coated underlayer, and the other optional layers in the lithographic stack may be removed following pattern transfer to the substrate using conventional techniques. Optionally, one or more of the layers of the stack may be removed following, or consumed during, pattern transfer to an underlying layer and prior to pattern transfer to the substrate. For example, pattern transfer to one or more of a silicon-containing layer, an organic antireflective coating layer, or the like may occur after the exposed photoresist layer is developed and before pattern transfer to the coated underlayer. The substrate is then further processed according to known processes to form an electronic device.

Also provided is a coated substrate that includes a layer of the inventive photoresist underlayer composition disposed on a substrate; and a second layer disposed on the layer of the photoresist underlayer composition. The second layer may be any one or more of the layers described herein, and in some instances may be a photoresist layer that is disposed on the layer of the photoresist underlayer composition. As used herein, the term “cured layer” refers to a layer derived from the photoresist underlayer composition after the composition has been disposed on a substrate and subsequently cured to form a coating layer or film, and is also referred to simply as the “photoresist underlayer.” In other words, curing the photoresist underlayer composition may be said to form a “cured layer,” which is the photoresist underlayer.

Still other aspects provide a layered article including a coated underlayer derived from the inventive photoresist underlayer composition. In an embodiment, a layered article may include a substrate; a coated underlayer disposed over the substrate; and a photoresist layer disposed over the coated underlayer.

The present inventive concept is further illustrated by the following examples, which are intended to be non-limiting. The compounds and reagents used herein are available commercially except where a procedure is provided below.

### EXAMPLES

### Synthesis Examples

### Synthesis of Polymer A-1

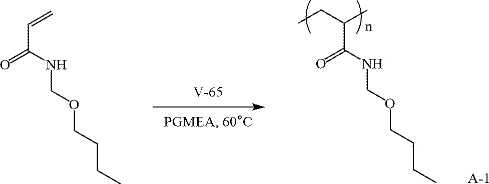

50.0 g of propylene glycol monomethyl ether acetate (PGMEA) was charged into 3-neck 250 mL round bottom flask (RBF) equipped with a temperature controller unit. The flask was heated to 60° C. under nitrogen. A mixture solution containing N-(butoxymethyl)acrylamide (BOAM, 40.0 g) and V-65 (6.52 g) dissolved in PGMEA (43.3 g) was prepared and fed into the reactor overt the span of 180 minutes. After the feeding was completed, the reactor was maintained at 60° C. for additional 60 minutes. The reactor was then allowed to cool to room temperature with stirring. The reaction mixture was precipitated with a mixture of heptane and MTBE (4:1 by volume) (10-fold excess by volume was added to the volume of the reaction mixture). The solvent was removed by filtration and the precipitate was then dried at 50° C. under vacuum for 1 day. A 30% solution of the product was then prepared using tetrahydrofuran (THF) and was precipitated from a mixture of heptane and MTBE (4:1 by volume). The solvents were removed by filtration and the resulting precipitate was then dried at 50° C. under vacuum for 1 day.

### Synthesis of Polymer A-2

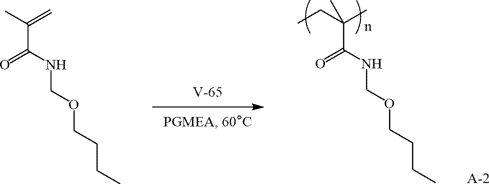

Polymer A-2 was prepared using a procedure similar to that used to prepare Polymer A-1, except N-(butoxymethyl)methacrylamide (BOMM, 40.0 g) was used instead of BOAM, and the amount of V-65 initiator was 5.80 g.

### Synthesis of Polymer A-3

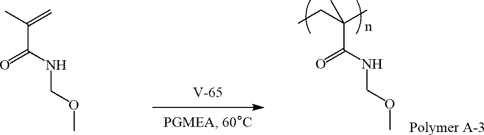

Polymer A-3 was prepared using a procedure similar to that used to prepare Polymer A-1, except N-(methoxymethyl)methacrylamide (MOMM, 40.0 g) was used instead of BOAM, and the amount of V-65 initiator was 7.69 g.

### Synthesis of BOMMM: N-(butoxymethyl)-N-methylmethacrylamide (BOMMM)

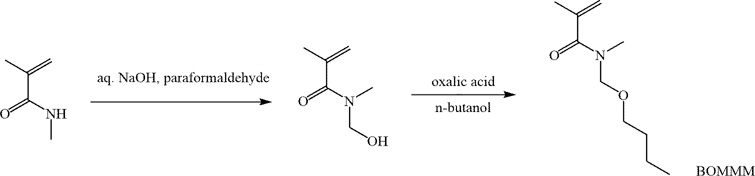

9.78 g of n-butyl alcohol and 0.07 g of 4-methoxyphenol (MEHQ) were charged into 3-neck 250 mL RBF set with a condenser and a static liquid apparatus. N-methacrylamide (29.2 g) was added to the contents of the RBF dropwise over 20 minutes while keeping the solution temperature to 30° C. After the dissolution of reagents, aqueous sodium hydroxide solution (10% solution) was added thereto, followed by 10.0 g of paraformaldehyde in a portion-wise manner over 20 minutes. The resulting mixture was heated at 55° C. for 30 minutes. The reaction solution was allowed to cool to room temperature. The pH was then adjusted to a pH of 5-6 by adding aqueous hydrochloric acid solution (35% solution). 0.3 g of oxalic acid and 52.45 g n-butyl alcohol were then added to the reaction solution, and the resulting mixture was heated at 90~95° C. for 6.5 hours while extracting water using the static liquid apparatus to obtain 126.57 g of reaction solution.

### Synthesis of Polymer A-4

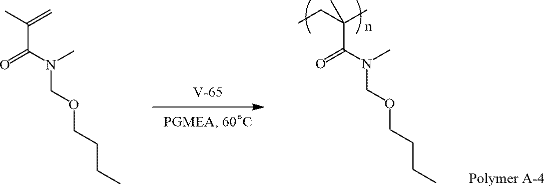

Polymer A-4 was prepared using a procedure similar to that used to prepare Polymer A-1, except BOMMM (40.0 g) was used instead of BOAM, and the amount of V-65 initiator was 5.36 g.

### Synthesis of BOEAM: N-(1-butoxyethyl)acrylamide (BOEAM)

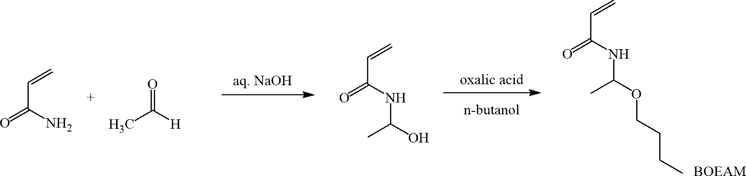

10.0 g of n-butyl alcohol and 0.07 g of 4-methoxyphenol (MEHQ) were charged into 3-neck 250 mL RBF set with a condenser and a static liquid apparatus. Acrylamide (21.4 g) was then added dropwise to the contents of the RBF over 20 minutes while holding the solution temperature at 30° C. After the dissolution of reagents, aqueous sodium hydroxide solution (10% solution) was added thereto, followed by 15.0 g of acetaldehyde in a portion-wise manner over 20 minutes. The resulting mixture was heated at 55° C. for 30 minutes. The reaction solution was allowed to cool to room temperature. The pH was then adjusted to a pH of 5-6 by adding hydrochloric acid (35% solution). 0.3 g of oxalic acid and 78.67 g of n-butyl alcohol were then added to the reaction solution, and the resulting mixture was heated at 90~95° C. for 6.5 hours while extracting water using the static liquid apparatus to obtain 119.63 g of reaction solution.

### Synthesis of Polymer A-5

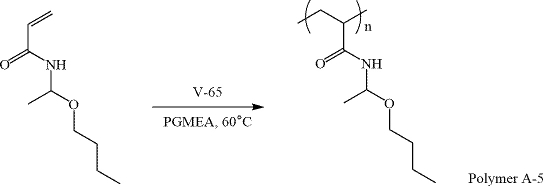

Polymer A-5 was prepared using a procedure similar to that used to prepare Polymer A-1, except BOEAM (40.0 g) was used instead of BOAM, and the amount of V-65 initiator was 5.80 g.

### Synthesis of POMA: N-(phenoxymethyl)acrylamide (POMA)

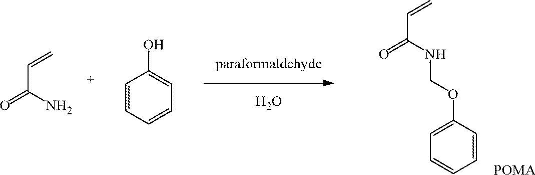

61.2 g of deionized (DI) water and 0.2 g of butylated hydroxytoluene (BHT) were charged into 3-neck 250 mL RBF set with a condenser and a static liquid apparatus. Then 56.4 g of phenol, 42.6 g of acrylamide, and 36.0 g of paraformaldehyde were added to the solution and the resulting mixture was heated at 110° C. for 2 hours. The solution was allowed to cool to room temperature and then concentrated under vacuum. The crude product was purified by silica gel column chromatography to obtain 29.0 g of product as a yellow oil.

### Synthesis of Polymer A-6

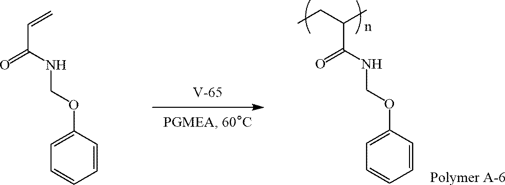

Polymer A-6 was prepared using a procedure similar to that used to prepare Polymer A-1, except POMA (40.0 g) was used instead of BOAM, and the amount of V-65 initiator was 5.61 g.

### Synthesis of Polymer A-7

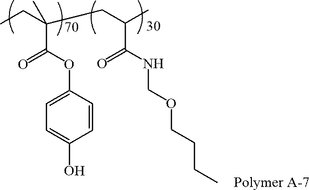

50.0 g of PGMEA was charged into 3-neck 250 mL RBF equipped with a temperature controller unit. The flask was heated to 60° C. under nitrogen. A mixture solution containing 4-hydroxyphenyl methacrylate (HQMA, 29.0 g), BOAM (11.0 g), and V-65 initiator (5.78 g) dissolved in PGMEA (43.3 g) was prepared and fed into the reactor overt the span of 180 minutes. After the feeding was completed, the reactor was maintained at 60° C. for additional 60 minutes. The reactor was then allowed to cool to room temperature with stirring. The reaction mixture was precipitated with mixture of heptane and MTBE (4:1 by volume) (10-fold excess by volume was added to the volume of the reaction mixture). The solvent was removed by filtration and the precipitate was then dried at 50° C. under vacuum for 1 day. A 30% solution of the product was then prepared using THF and was precipitated from a mixture of heptane and MTBE (4:1 by volume). The solvents were removed by filtration and the precipitate was then dried at 50° C. under vacuum for 1 day.

### Synthesis of Polymer B-1

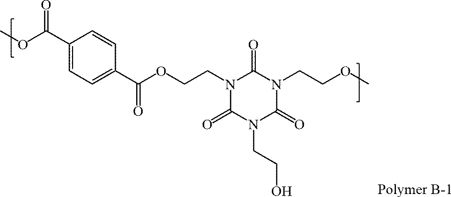

A 250 mL RBF was charged with 46.09 g of tris(2-hydroxyethyl)isocyanurate, 21.6 of tris(2-carboxyethyl)isocyanurate, 1.35 g of para-toluene sulfonic acid monohydrate, 31.15 g of dimethyl terephthalate, and 52 g of anisole. The mixture was then heated to 140-150° C. and the contents were vigorously stirred. Methanol along with anisole were slowly removed by distillation from the reaction. The polymer solution was then diluted by adding 100 g of HBM. The mixture was precipitated from isopropanol. The polymer was collected and dried under vacuum at 40-60° C. overnight. M_{w} was 3000 g/mol with a PDI of 1.4 (GPC).

### Synthesis of Polymer B-2

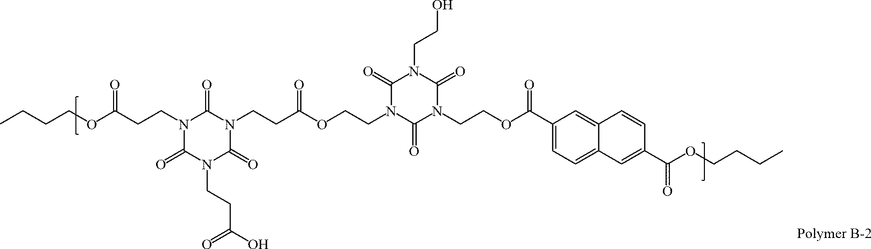

A 250 mL RBF was charged with 39.8 g of tris(2-hydroxyethyl)isocyanurate, 17.5 of tris(2-carboxyethyl)isocyanurate, 0.73 g of para-toluene sulfonic acid monohydrate, 32.1 g of dibutylnaphthalene dicarboxylate, 67 g of anisole, and 100 g of 1-butanol. The mixture was then heated to 140-160° C., and the contents were vigorously stirred. Butanol and anisole were slowly removed by distillation from the reaction. The polymer solution was then diluted by adding 100 g of THF. The mixture was precipitated from a combination of MTBE and isopropanol (1:1 by volume). The polymer was collected and dried under vacuum at 40-60° C. for 12 hours. M_{w} was 3000 g/mol with a PDI of 1.30 (GPC).

### Synthesis of Polymer B-3

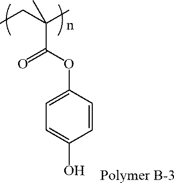

60.0 g of ethyl lactate was charged into a 3-neck 250 mL RBF equipped with a temperature controller unit. The reactor was heated to 90° C. 4-hydroxyphenyl methacrylate (HQMA, 40.0 g) and V-601 initiator (10.34 g) were dissolved in cyclohexanone (60.0 g), and this prepared mixture solution was then fed into the reactor over 180 minutes. After feeding was completed, the reactor was maintained at 90° C. for an additional 60 minutes. The reactor was then allowed to cool to room temperature with stirring. The reaction mixture was precipitated with a mixture of MTBE and heptane (4:6 by volume) (using a 10-fold excess by volume). The solvent was removed by decanting and the precipitate was then dried in the air. The resulting white solid was dissolved in THF (120 g) and precipitated from a combination of MTBE and heptane (4:6 by volume).

### Underlayer Compositions

Table 1 shows the underlayer compositions for Examples 1 to 11 and Comparative Examples 1 to 6 that were prepared by mixing the components in the amounts shown. Each composition further included 5 mg of 2,4,6-trimethylpyridinium p-toluenesulfonate, 4.8 g of methyl-2-hydroxy isobutyrate, and 4.8 g of PGMEA. Prior to use, the solutions were filtered through a polytetrafluorethylene (PTFE) filter having a pore diameter of 0.45 µm.

TABLE 1

| | | |
|---|---|---|
| | Polymer 1 | Polymer 2 |
| Example 1 | A-1 (79 mg) | B-1 (316 mg) |
| Example 2 | A-2 (79 mg) | B-1 (316 mg) |
| Example 3 | A-3 (79 mg) | B-1 (316 mg) |
| Example 4 | A-4 (79 mg) | B-1 (316 mg) |
| Example 5 | A-5 (79 mg) | B-1 (316 mg) |
| Example 6 | A-1 (79 mg) | B-2 (316 mg) |
| Example 7 | A-2 (79 mg) | B-2 (316 mg) |
| Example 8 | A-3 (79 mg) | B-2 (316 mg) |
| Example 9 | A-4 (79 mg) | B-2 (316 mg) |
| Example 10 | A-5 (79 mg) | B-2 (316 mg) |
| Example 11 | A-7 (395 mg) | -- |
| Comparative Example 1 | C-1 (80 mg) | B-1 (315 mg) |
| Comparative Example 2 | C-2 (80 mg) | B-1 (315 mg) |
| Comparative Example 3 | C-1 (80 mg) | B-2 (316 mg) |
| Comparative Example 4 | C-2 (80 mg) | B-2 (316 mg) |
| Comparative Example 5 | C-1 (80 mg) | B-3 (315 mg) |
| Comparative Example 6 | C-2 (80 mg) | B-3 (315 mg) |

The following abbreviations were used in Table 1: C-1 is tetramethoxymethyl glycoluril; and C-2 is hexakis(methoxymethyl)-1,3,5-triazine-2,4,6-triamine.

### Solvent Resistance Evaluation

Each of the compositions in Table 1 was spin-coated onto respective bare 200-mm silicon wafers at 1500 rpm,and then cured at 205° C. for 60 seconds to form a cured coating layer as a film. The initial thickness of the film on the silicon wafer was measured by ellipsometry (M2000 ellipsometer, J.A Woolam), and then 30 mL of PGMEA was contacted to a surface of the wafer and left for one minute to be fixed in the surface of the wafer. Thereafter, the wafer was spin-dried at 4,000 rpm for one minute, and the thickness of the remaining film was measured by ellipsometry. Then, the difference in thickness (i.e., film loss) was calculated based on the film thickness before and after contacting with PGME/spin drying. The results thereof are shown in Table 2 as film loss (in angstroms, Å).

### Sublimation Resistance Evaluation

To determine the amount of material that sublimes from the film during the curing process, a test procedure was employed that measures the amount of material that condenses onto a quartz crystal placed approximately 1 cm above the polymer film during the process of curing the film on a bare silicon wafer using a hot plate. Each of the compositions in Table 1 was spin-coated onto respective bare 200-mm silicon wafer at 1500 rpm without a post bake heating step. Sublimation from the film while heating at 205° C. for 60 seconds to form a cured film was measured by Quartz Crystal Microbalance (QCM). The cured film had a thickness of 100 nm. The results thereof are shown in Table 2 as sublimation mass absorbed (µg) from the curing films.

### Glass Transition Temperature of Cured Films

Each of the compositions in Table 1 was spin-coated onto respective bare 200-mm silicon wafers at 1500 rpm, and then cured at 215° C. for 60 seconds to form a cured coating layer as a film having a thickness of 900 nm. The coated wafer was cleaved into 2 cm × 2 cm sections and loaded into the heat cell of an ellipsometer (M2000 ellipsometer, J. A. Woollam). Differential scanning calorimetry (DSC) was used to determine glass transition temperature (T_{g}) using 2 cycles of heating to 250° C. at a rate of 10° C./s and cooling to 30° C. at a rate of 10° C./s. The glass transition temperature (T_{g}) was calculated from the first cooling profile using Universal Analysis software. The results thereof are shown in Table 2 as T_{g} (°C).

TABLE 2

| | Polymer 1 | Polymer 2 | Film loss (Å) | Sublimation amount (µg) | T_{g} (°C) |
|---|---|---|---|---|---|
| Example 1 | A-1 | B-1 | -0.2 | 3 | >250 |
| Example 2 | A-2 | B-1 | -0.8 | 6 | >250 |
| Example 3 | A-3 | B-1 | -0.4 | 3 | >250 |
| Example 4 | A-4 | B-1 | -0.6 | 3 | >250 |
| Example 5 | A-5 | B-1 | -0.3 | 6 | >250 |
| Comparative Example 1 | C-1 | B-1 | -1.2 | 39 | 195 |
| Comparative Example 2 | C-2 | B-1 | -1.4 | 33 | 219 |
| Example 6 | A-1 | B-2 | -0.4 | 3 | >250 |
| Example 7 | A-2 | B-2 | -0.7 | 3 | >250 |
| Example 8 | A-3 | B-2 | -0.2 | 0 | >250 |
| Example 9 | A-4 | B-2 | -0.3 | 3 | >250 |
| Example 10 | A-5 | B-2 | -0.8 | 6 | >250 |
| Comparative Example 3 | C-2 | B-2 | -1.5 | 36 | 186 |
| Comparative Example 4 | C-1 | B-3 | -1.4 | 39 | 199 |
| Example 11 | A-7 | -- | -0.4 | 3 | >250 |
| Comparative Example 5 | C-1 | B-3 | -1.1 | 48 | 225 |
| Comparative Example 6 | C-2 | B-3 | -1.5 | 42 | 231 |

As can be seen from Table 2, the samples of Examples 1-11 achieved greater solvent resistance as evidenced by less film loss (film losses from 0.2 to 0.8 Å) as compared with Comparative Examples 1-6 (film losses from 1.1 to 1.5 Å). Examples 1-11 were less susceptible to sublimation, as the resulting sublimation amount was from 0 to 6 µg. In contrast, heating Comparative Examples 1-6 resulted in sublimation films in amounts from 33 to 48 µg. In addition, each of Examples 1-11 has a film T_{g} of greater than 250° C., whereas none of Comparative Examples 1-6 has a film T_{g} that exceeds 231° C. Hence, the inventive underlayer compositions of Examples 1 to 11 demonstrated greater film density.

### Pattern Coating Evaluation

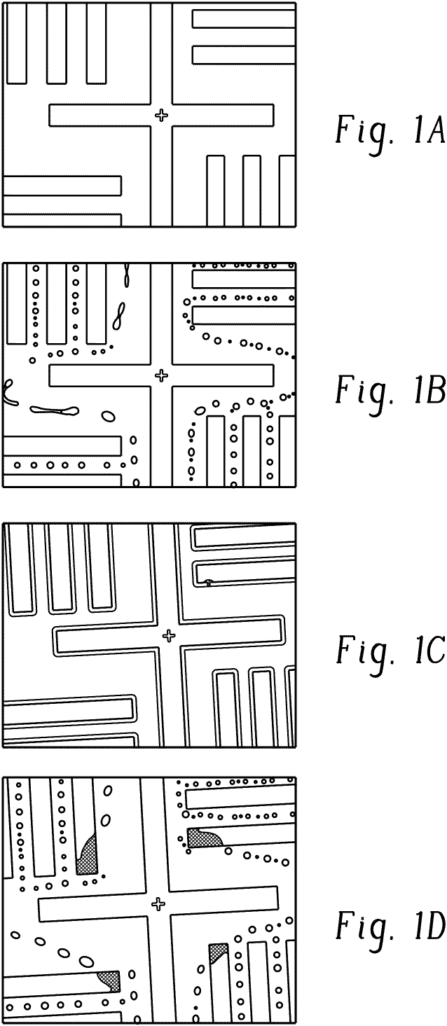

The underlayer compositions of Example 1, Comparative Example 1, Example 6, and Comparative Example 3 were spin-coated on SiO₂ substrates having trenches of 1 µm CD and 107.7 nm depth, followed by heating at 205° C. for one minute. Thereafter, the coating stability and filling properties of the underlayer compositions on the patterns were observed using an optical microscope. FIGS. 1A to 1D show optical microscope images of patterns coated with the underlayer compositions of Example 1, Comparative Example 1, Example 6, and Comparative Example 3, respectively. It was discovered that a coating film of the composition of Example 1 and Example 6 were coated well to correspond to the pattern. However, a pull-back phenomenon was observed for the coating films of Comparative Example 1 and Comparative Example 3, resulting in tears in the pattern during the heat process.

### Lithographic Performance

The underlayer compositions of Example 1 and Comparative Example 1 were spin-coated on silicon wafers and then baked at 205° C. using a TEL Mark 8 wafer coating track machine to generate bottom antireflective coatings. Next, a DuPont EPIC™ 2150 photoresist was spin coated on top of the antireflective film, and baked at 110° C. for 60 seconds to give photoresist film having a thickness of 170 nm. The photoresist was then exposed through a target mask using a 193 nm ArF wafer stepper with a 0.93 NA (0.82/0.53 annular setting). The photoresist film was then subjected to post-exposure baking at 115° C. for 60 seconds, and then developed using a Shipley MF CD-26 developer (2.38% TMAH) in a standard 60-second single-puddle process. Scanning electron microscopy (SEM) at 60,000 magnification was used to examine the quality of the resist patterns.

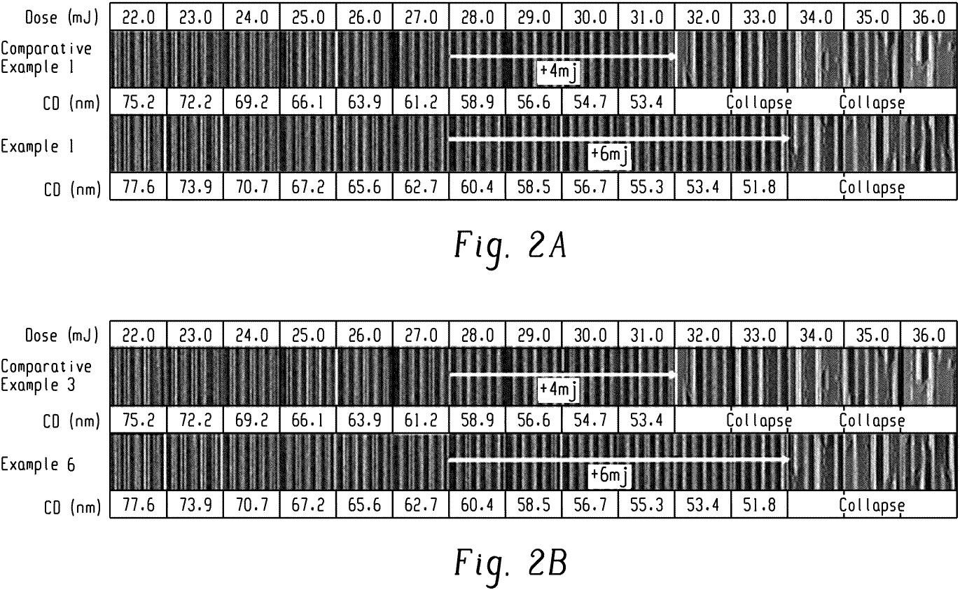

The SEM results in FIG. 2A show a 65 nm CD for 160 nm pitch line and space pattern using the antireflective composition of Example 1 and Comparative Example 1. When Example 1 was used as bottom antireflective film, better collapse margin was observed over when Comparative Example 1 was used, presumably due to higher film density of Example 1 as proved by higher film T_{g}. The same tendency was observed when Example 6 and Comparative Example 3 were used as bottom antireflective film, as depicted in FIG. 2B.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

1. A photoresist underlayer composition, comprising
a first polymer comprising a first structural unit derived from an N-(alkoxymethyl) (meth)acrylic amide monomer;
a second structural unit comprising an aromatic group, a heterocyclic group, an ester group, an amide group, or a combination thereof, wherein the second structural unit further comprises a crosslinkable group;
wherein the first polymer comprises the second structural unit, the photoresist underlayer composition further comprises a second polymer comprising the second structural unit, or a combination thereof,
a thermal acid generator; and
a solvent.

2. The photoresist underlayer composition of claim 1, wherein
the first polymer comprises the first structural unit and the second structural unit, and
the second structural unit comprises a C₆₋₆₀ aryl group and the crosslinkable group.

3. The photoresist underlayer composition of claim 1, further comprising the second polymer, wherein the second polymer comprises the second structural unit and the crosslinkable group, and wherein the second polymer further comprises a third structural unit comprising a substituted cyanurate.

4. The photoresist underlayer composition of claim 1, wherein the N-(alkoxymethyl) (meth)acrylic amide monomer is of Formula (1): 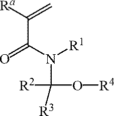
wherein, in Formula (1),
R^{a} is hydrogen, fluorine, cyano, or substituted or unsubstituted C₁₋₁₀ alkyl;
R¹ is hydrogen, or substituted or unsubstituted C₁₋₁₀ alkyl;
R² and R³ are each independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ heteroarylalkyl, or substituted or unsubstituted C₄₋₃₀ alkylheteroaryl;
each of R² and R³ optionally further comprises a divalent linking group as part of their structure;
R² and R³ optionally form a ring via a single bond or a divalent linking group, wherein the ring is substituted or unsubstituted;
R⁴ is hydrogen, substituted or unsubstituted C₁₋₂₀ alkyl, substituted or unsubstituted C₃₋₂₀ cycloalkyl, substituted or unsubstituted C₂₋₂₀ heterocycloalkyl, substituted or unsubstituted C₆₋₂₄ aryl, substituted or unsubstituted C₇₋₂₅ arylalkyl, substituted or unsubstituted C₇₋₂₅ alkylaryl, substituted or unsubstituted C₃₋₂₀ heteroaryl, substituted or unsubstituted C₄₋₂₀ heteroarylalkyl, or substituted or unsubstituted C₄₋₂₀ alkylheteroaryl; and
one of R² or R³ optionally forms a heterocyclic ring together with R⁴ via a single bond or a divalent linking group, wherein the heterocyclic ring is substituted or unsubstituted.

5. The photoresist underlayer composition of claim 4, wherein
R^{a} is hydrogen, or unsubstituted C₁₋₃ alkyl;
R¹ is hydrogen or methyl;
R² and R³ are each independently hydrogen, or substituted or unsubstituted C₁₋₁₀ alkyl; and
R⁴ is substituted or unsubstituted C₁₋₁₀ alkyl, substituted or unsubstituted C₃₋₁₀ cycloalkyl, substituted or unsubstituted C₂₋₁₀ heterocycloalkyl, substituted or unsubstituted C₆₋₁₄ aryl, or substituted or unsubstituted C₃₋₂₀ heteroaryl.

6. The photoresist underlayer composition of claim 1, wherein the second structural unit comprises a heterocyclic group comprising a substituted cyanurate structural unit that is derived from a compound represented by Formula (4), Formula (5), or a combination thereof: 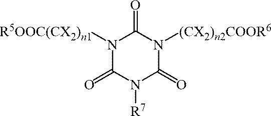 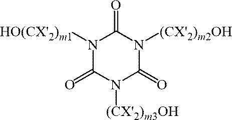
wherein, in Formulae (4) and (5),
R⁵ and R⁶ are each independently hydrogen, substituted or unsubstituted C₁₋₃₀ alkyl, substituted or unsubstituted C₃₋₃₀ cycloalkyl, substituted or unsubstituted C₃₋₃₀ heterocycloalkyl, substituted or unsubstituted C₆₋₃₀ aryl, or substituted or unsubstituted C₃₋₃₀ heteroaryl;
R⁷ is hydrogen, —COOH, substituted or unsubstituted C₁₋₃₀ alkyl, substituted or unsubstituted C₂₋₃₀ alkenyl, substituted or unsubstituted C₂₋₃₀ alkynyl, substituted or unsubstituted C₂₋₃₀ alkanoyl, substituted or unsubstituted C₁-C₃₀ alkoxy, substituted or unsubstituted C₁-C₃₀ alkylthio, substituted or unsubstituted C₁-C₃₀ alkylsulfinyl, substituted or unsubstituted C₁-C₃₀ alkylsulfonyl, substituted or unsubstituted C₂-C₃₀ alkoxycarbonyl, substituted or unsubstituted C₃₋₂₀ cycloalkenyl, substituted or unsubstituted C₃₋₂₀ heterocycloalkenyl, substituted or unsubstituted C₆-C₃₀ aryl, substituted or unsubstituted C₇-C₃₀ alkylaryl, substituted or unsubstituted C₇-C₃₀ arylalkyl, substituted or unsubstituted C₃₋₃₀ heteroaryl, substituted or unsubstituted C₄₋₃₀ alkylheteroaryl, or substituted or unsubstituted C₄₋₃₀ heteroarylalkyl;
each X and X′ is independently hydrogen, or substituted or unsubstituted C₁₋₁₀ alkyl; and
n1, n2, m1, m2, and m3 are each independently an integer from 1 to 10.

7. A coated substrate, comprising:
a layer of the photoresist underlayer composition of claim 1 te-6-disposed on a substrate; and
a second layer disposed on the layer of the photoresist underlayer composition.

8. A method of forming a pattern, the method comprising:
applying a layer of the photoresist underlayer composition of claim 1 on a substrate;
curing the applied photoresist underlayer composition to form a photoresist underlayer; and
forming a photoresist layer over the photoresist underlayer.

9. The method of claim 8, further comprising forming a silicon-containing layer, an organic antireflective coating layer, or a combination thereof, above the photoresist underlayer prior to forming the photoresist layer.

10. The method of claim 8, further comprising patterning the photoresist layer and transferring a pattern from the patterned photoresist layer to the photoresist underlayer and to a layer below the photoresist underlayer.

11. The coated substrate of claim 7, wherein
the first polymer comprises the first structural unit and the second structural unit, and
the second structural unit comprises a C₆₋₆₀ aryl group and the crosslinkable group.

12. The coated substrate of claim 7, wherein the photoresist underlayer composition further comprises the second polymer, wherein the second polymer comprises the second structural unit and the crosslinkable group, and wherein the second polymer further comprises a third structural unit comprising a substituted cyanurate.

13. The coated substrate of claim 7, wherein the N-(alkoxymethyl) (meth)acrylic amide monomer is of Formula (1): 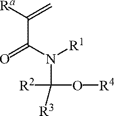
wherein, in Formula (1),
R^{a} is hydrogen, fluorine, cyano, or substituted or unsubstituted C₁₋₁₀ alkyl;
R¹ is hydrogen, or substituted or unsubstituted C₁₋₁₀ alkyl;
R² and R³ are each independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ heteroarylalkyl, or substituted or unsubstituted C₄₋₃₀ alkylheteroaryl;
each of R² and R³ optionally further comprises a divalent linking group as part of their structure;
R² and R³ optionally form a ring via a single bond or a divalent linking group, wherein the ring is substituted or unsubstituted;
R⁴ is hydrogen, substituted or unsubstituted C₁₋₂₀ alkyl, substituted or unsubstituted C₃₋₂₀ cycloalkyl, substituted or unsubstituted C₂₋₂₀ heterocycloalkyl, substituted or unsubstituted C₆₋₂₄ aryl, substituted or unsubstituted C₇₋₂₅ arylalkyl, substituted or unsubstituted C₇₋₂₅ alkylaryl, substituted or unsubstituted C₃₋₂₀ heteroaryl, substituted or unsubstituted C₄₋₂₀ heteroarylalkyl, or substituted or unsubstituted C₄₋₂₀ alkylheteroaryl; and
one of R² or R³ optionally forms a heterocyclic ring together with R⁴ via a single bond or a divalent linking group, wherein the heterocyclic ring is substituted or unsubstituted.

14. The coated substrate of claim 13, wherein
R^{a} is hydrogen, or unsubstituted C₁₋₃ alkyl;
R¹ is hydrogen or methyl;
R² and R³ are each independently hydrogen, or substituted or unsubstituted C₁₋₁₀ alkyl; and
R⁴ is substituted or unsubstituted C₁₋₁₀ alkyl, substituted or unsubstituted C₃₋₁₀ cycloalkyl, substituted or unsubstituted C₂₋₁₀ heterocycloalkyl, substituted or unsubstituted C₆₋₁₄ aryl, or substituted or unsubstituted C₃₋₂₀ heteroaryl.

15. The coated substrate of claim 7, wherein the second structural unit comprises a heterocyclic group comprising a substituted cyanurate structural unit that is derived from a compound represented by Formula (4), Formula (5), or a combination thereof: 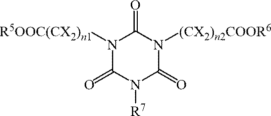 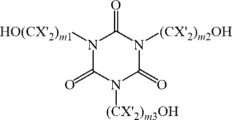
wherein, in Formulae (4) and (5),
R⁵ and R⁶ are each independently hydrogen, substituted or unsubstituted C₁₋₃₀ alkyl, substituted or unsubstituted C₃₋₃₀ cycloalkyl, substituted or unsubstituted C₃₋₃₀ heterocycloalkyl, substituted or unsubstituted C₆₋₃₀ aryl, or substituted or unsubstituted C₃₋₃₀ heteroaryl;
R⁷ is hydrogen, —COOH, substituted or unsubstituted C₁₋₃₀ alkyl, substituted or unsubstituted C₂₋₃₀ alkenyl, substituted or unsubstituted C₂₋₃₀ alkynyl, substituted or unsubstituted C₂₋₃₀ alkanoyl, substituted or unsubstituted C₁-C₃₀ alkoxy, substituted or unsubstituted C₁-C₃₀ alkylthio, substituted or unsubstituted C₁-C₃₀ alkylsulfinyl, substituted or unsubstituted C₁-C₃₀ alkylsulfonyl, substituted or unsubstituted C₂-C₃₀ alkoxycarbonyl, substituted or unsubstituted C₃₋₂₀ cycloalkenyl, substituted or unsubstituted C₃₋₂₀ heterocycloalkenyl, substituted or unsubstituted C₆-C₃₀ aryl, substituted or unsubstituted C₇-C₃₀ alkylaryl, substituted or unsubstituted C₇-C₃₀ arylalkyl, substituted or unsubstituted C₃₋₃₀ heteroaryl, substituted or unsubstituted C₄₋₃₀ alkylheteroaryl, or substituted or unsubstituted C₄₋₃₀ heteroarylalkyl;
each X and X′ is independently hydrogen, or substituted or unsubstituted C₁₋₁₀ alkyl; and
n1, n2, m1, m2, and m3 are each independently an integer from 1 to 10.

16. The method of claim 8, wherein
the first polymer comprises the first structural unit and the second structural unit, and
the second structural unit comprises a C₆₋₆₀ aryl group and the crosslinkable group.

17. The method of claim 8, wherein the photoresist underlayer composition further comprises the second polymer, wherein the second polymer comprises the second structural unit and the crosslinkable group, and wherein the second polymer further comprises a third structural unit comprising a substituted cyanurate.

18. The method of claim 8, wherein the N-(alkoxymethyl) (meth)acrylic amide monomer is of Formula (1): 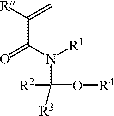
wherein, in Formula (1),
R^{a} is hydrogen, fluorine, cyano, or substituted or unsubstituted C₁₋₁₀ alkyl;
R¹ is hydrogen, or substituted or unsubstituted C₁₋₁₀ alkyl;
R² and R³ are each independently hydrogen, substituted or unsubstituted C₁₋₃₀ alkyl, substituted or unsubstituted C₁₋₃₀ heteroalkyl, substituted or unsubstituted C₃₋₃₀ cycloalkyl, substituted or unsubstituted C₂₋₃₀ heterocycloalkyl, substituted or unsubstituted C₂₋₃₀ alkenyl, substituted or unsubstituted C₆₋₃₀ aryl, substituted or unsubstituted C₇₋₃₀ arylalkyl, substituted or unsubstituted C₇₋₃₀ alkylaryl, substituted or unsubstituted C₃₋₃₀ heteroaryl, substituted or unsubstituted C₄₋₃₀ heteroarylalkyl, or substituted or unsubstituted C₄₋₃₀ alkylheteroaryl;
each of R² and R³ optionally further comprises a divalent linking group as part of their structure;
R² and R³ optionally form a ring via a single bond or a divalent linking group, wherein the ring is substituted or unsubstituted;
R⁴ is hydrogen, substituted or unsubstituted C₁₋₂₀ alkyl, substituted or unsubstituted C₃₋₂₀ cycloalkyl, substituted or unsubstituted C₂₋₂₀ heterocycloalkyl, substituted or unsubstituted C₆₋₂₄ aryl, substituted or unsubstituted C₇₋₂₅ arylalkyl, substituted or unsubstituted C₇₋₂₅ alkylaryl, substituted or unsubstituted C₃₋₂₀ heteroaryl, substituted or unsubstituted C₄₋₂₀ heteroarylalkyl, or substituted or unsubstituted C₄₋₂₀ alkylheteroaryl; and
one of R² or R³ optionally forms a heterocyclic ring together with R⁴ via a single bond or a divalent linking group, wherein the heterocyclic ring is substituted or unsubstituted.

19. The method of claim 18, wherein
R^{a} is hydrogen, or unsubstituted C₁₋₃ alkyl;
R¹ is hydrogen or methyl;
R² and R³ are each independently hydrogen, or substituted or unsubstituted C₁₋₁₀ alkyl; and
R⁴ is substituted or unsubstituted C₁₋₁₀ alkyl, substituted or unsubstituted C₃₋₁₀ cycloalkyl, substituted or unsubstituted C₂₋₁₀ heterocycloalkyl, substituted or unsubstituted C₆₋₁₄ aryl, or substituted or unsubstituted C₃₋₂₀ heteroaryl.

20. The method of claim 8, wherein the second structural unit comprises a heterocyclic group comprising a substituted cyanurate structural unit that is derived from a compound represented by Formula (4), Formula (5), or a combination thereof: 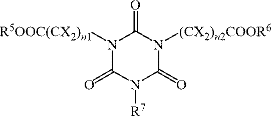 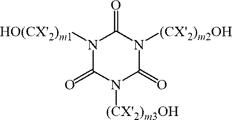
wherein, in Formulae (4) and (5),
R⁵ and R⁶ are each independently hydrogen, substituted or unsubstituted C₁₋₃₀ alkyl, substituted or unsubstituted C₃₋₃₀ cycloalkyl, substituted or unsubstituted C₃₋₃₀ heterocycloalkyl, substituted or unsubstituted C₆₋₃₀ aryl, or substituted or unsubstituted C₃₋₃₀ heteroaryl;
R⁷ is hydrogen, —COOH, substituted or unsubstituted C₁₋₃₀ alkyl, substituted or unsubstituted C₂₋₃₀ alkenyl, substituted or unsubstituted C₂₋₃₀ alkynyl, substituted or unsubstituted C₂₋₃₀ alkanoyl, substituted or unsubstituted C₁-C₃₀ alkoxy, substituted or unsubstituted C₁-C₃₀ alkylthio, substituted or unsubstituted C₁-C₃₀ alkylsulfinyl, substituted or unsubstituted C₁-C₃₀ alkylsulfonyl, substituted or unsubstituted C₂-C₃₀ alkoxycarbonyl, substituted or unsubstituted C₃₋₂₀ cycloalkenyl, substituted or unsubstituted C₃₋₂₀ heterocycloalkenyl, substituted or unsubstituted C₆-C₃₀ aryl, substituted or unsubstituted C₇-C₃₀ alkylaryl, substituted or unsubstituted C₇-C₃₀ arylalkyl, substituted or unsubstituted C₃₋₃₀ heteroaryl, substituted or unsubstituted C₄₋₃₀ alkylheteroaryl, or substituted or unsubstituted C₄₋₃₀ heteroarylalkyl;
each X and X′ is independently hydrogen, or substituted or unsubstituted C₁₋₁₀ alkyl; and
n1, n2, m1, m2, and m3 are each independently an integer from 1 to 10.
